(19) United States
(12) Patent Application Publication
(10) Pub. No.: US 2024/0333238 A1
(43) Pub. Date: Oct. 3, 2024

(54) TRANSFORMER AND RADIO FREQUENCY MODULE

(71) Applicant: Murata Manufacturing Co., Ltd., Nagaokakyo-shi (JP)

(72) Inventor: Kyohei MORITA, Nagaokakyo-shi (JP)

(73) Assignee: Murata Manufacturing Co., Ltd., Nagaokakyo-shi (JP)

(21) Appl. No.: 18/639,997

(22) Filed: Apr. 19, 2024

Related U.S. Application Data
(63) Continuation of application No. PCT/JP2022/044288, filed on Nov. 30, 2022.

(30) Foreign Application Priority Data
Dec. 28, 2021 (JP) 2021-214797

(51) Int. Cl. H03F 3/24; H01F 19/04; H01F 27/29; H03F 1/56; H03H 7/42

(52) U.S. Cl. CPC H03F 3/245; H01F 19/04; H01F 27/292; H03F 1/565; H03H 7/42; H03F 2200/318; H03F 2200/451

(57) ABSTRACT

A transformer that can increase a coupling coefficient of the transformer by suppressing a signal loss in the transformer. The transformer includes a balanced side coil, an unbalanced side coil, a wiring pattern portion, and a multilayer substrate. The balanced side coil has a first end, a second end, and an intermediate tap. The unbalanced side coil has a third end. The wiring pattern portion is electrically connected to the intermediate tap. The multilayer substrate has a plurality of dielectric layers, and the balanced side coil, the unbalanced side coil, and the wiring pattern portion are disposed on dielectric layers different from each other in the plurality of dielectric layers. The balanced side coil and the unbalanced side coil overlap each other in a plan view from a thickness direction of the multilayer substrate.

### CROSS-REFERENCE TO RELATED APPLICATIONS

This is a continuation application of PCT/JP2022/044288, filed on Nov. 30, 2022, designating the United States of America, which is based on and claims priority to Japanese Patent Application No. JP 2021-214797, filed on Dec. 28, 2021. The entire contents of the above-identified applications, including the specifications, drawings and claims, are incorporated herein by reference in their entirety.

### TECHNICAL FIELD

The present disclosure relates to a transformer and a radio frequency module.

### BACKGROUND ART

A power amplifier disclosed in Patent Document 1 includes a transformer. The transformer includes a first coil (a balanced side coil), a second coil (an unbalanced side coil), and wiring (a wiring pattern portion). A first input signal and a second input signal, which are amplified by a first amplifier, are input to the first coil. The second coil is magnetically coupled to the first coil, and outputs a combined signal of the first input signal and the second input signal which are amplified. The wiring connects a midpoint of the first coil and a terminal.

### CITATION LIST

### Patent Document

Patent Document 1: Japanese Unexamined Patent Application Publication No. 2010-147574

### SUMMARY OF DISCLOSURE

### Technical Problem

In the power amplifier disclosed in Patent Document 1, assuming the number of turns of the first coil and the second coil is increased to increase a coupling coefficient of the transformer, the increase in size of the transformer occurs. Further, assuming a line width of each of the first coil and the second coil is reduced to suppress the increase in size, the electric resistance of each of the first coil and the second coil increases, so that a signal loss increases in the transformer.

In view of the above problem, an object of the present disclosure is to provide a transformer that is capable of increasing a coupling coefficient of a transformer while suppressing a signal loss in the transformer, and a radio frequency module that includes the transformer.

### Solution to Problem

A transformer according to an aspect of the present disclosure includes a balanced side coil, an unbalanced side coil, an external connection wiring pattern portion, and a multilayer substrate. The balanced side coil has a first end, a second end, and an intermediate tap included between the first end and the second end. The unbalanced side coil has a third end and a fourth end. The fourth end is grounded. The wiring pattern portion is electrically connected to the intermediate tap. The multilayer substrate has a plurality of dielectric layers. The balanced side coil, the unbalanced side coil, and the wiring pattern portion are disposed on dielectric layers different from each other in the plurality of dielectric layers of the multilayer substrate. The balanced side coil and the unbalanced side coil at least partially overlap each other in a plan view from a thickness direction of the multilayer substrate. The wiring pattern portion has an overlapping portion that overlaps the unbalanced side coil along a peripheral direction in a plan view from the thickness direction of the multilayer substrate.

A radio frequency module according to an aspect of the present disclosure includes the transformer, a first input terminal, a second input terminal, a first power amplifier, and a second power amplifier. The first power amplifier amplifies a first balanced signal input from the first input terminal and outputs a resulting signal to the first end of the transformer. The second power amplifier amplifies a second balanced signal input from the second input terminal, and outputs a resulting signal to the second end of the transformer.

### Advantageous Effects of Disclosure

According to the transformer according to the aspect of the present disclosure and the radio frequency module including the transformer, there is an advantage that a coupling coefficient of the transformer can be increased while suppressing a signal loss in the transformer.

### BRIEF DESCRIPTION OF DRAWINGS

FIG. 1 is a circuit diagram of a radio frequency module according to Embodiment 1.

FIG. 2 is an exploded perspective view of a transformer of the radio frequency module.

FIG. 3 is a plan view of a first dielectric layer of a multilayer substrate of the transformer.

FIG. 4 is a plan view of a second dielectric layer of the multilayer substrate of the transformer.

FIG. 5 is a plan view of a third dielectric layer of the multilayer substrate of the transformer.

FIG. 6 is a plan view of a fourth dielectric layer of the multilayer substrate of the transformer.

FIG. 7 is a plan view explaining an overlapping state of a wiring pattern portion, a first unbalanced side coil portion, and a second unbalanced side coil portion of the transformer.

FIG. 8 is a plan view of a wiring pattern portion of a comparative example.

FIG. 9A is a plan view of a wiring pattern portion according to Modification Example 1. FIG. 9B is a plan view explaining an overlapping state of a wiring pattern portion, a first unbalanced side coil portion, and a second unbalanced side coil portion according to Modification Example 1.

FIG. 10A is a plan view of a wiring pattern portion according to Modification Example 2. FIG. 10B is a plan view explaining an overlapping state of a wiring pattern portion, a first unbalanced side coil portion, and a second unbalanced side coil portion according to Modification Example 2.

FIG. 11A is a plan view of a wiring pattern portion according to Modification Example 3. FIG. 11B is a plan view explaining an overlapping state of a wiring pattern portion, a first unbalanced side coil portion, and a second unbalanced side coil portion according to Modification Example 3.

FIG. 12A is a plan view of a wiring pattern portion according to Modification Example 4. FIG. 12B is a plan view explaining an overlapping state of a wiring pattern portion, a first unbalanced side coil portion, and a second unbalanced side coil portion according to Modification Example 4.

FIG. 13 is a plan view of a mounting substrate of a radio frequency module according to Modification Example 5.

FIG. 14 is a cross-sectional view taken along a line Y-Y of FIG. 13.

FIG. 15 is an exploded perspective view of a transformer according to Embodiment 2.

FIG. 16 is a plan view of a first dielectric layer of a multilayer substrate of the transformer.

FIG. 17 is a plan view of a second dielectric layer of the multilayer substrate of the transformer.

FIG. 18 is a plan view of a third dielectric layer of the multilayer substrate of the transformer.

FIG. 19 is a plan view of a fourth dielectric layer of the multilayer substrate of the transformer.

FIG. 20 is a plan view of a fifth dielectric layer of the multilayer substrate of the transformer.

FIG. 21 is a plan view for explaining an overlapping state of a wiring pattern portion, a first unbalanced side coil portion, and a second unbalanced side coil portion in the transformer.

### DESCRIPTION OF EMBODIMENTS

Hereinafter, a transformer and a radio frequency module including the transformer according to an embodiment will be described with reference to the accompanying drawings. For components described in the specification and the drawings, the size, the thickness, and the dimensional relationship therebetween described in the specification and the drawings are examples, and the components are not limited to the examples described in the specification and the drawings.

### Embodiment 1

### (1) Circuit Configuration of Radio Frequency Module

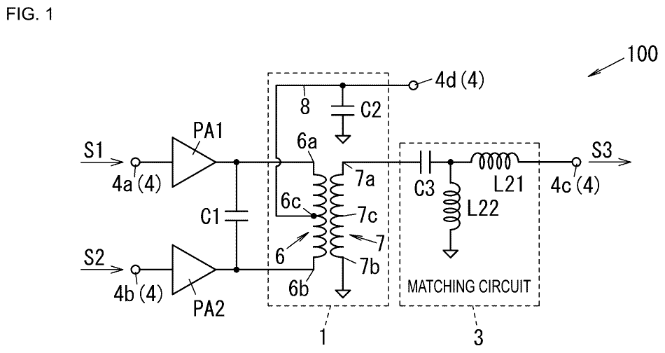

An example of a circuit configuration of a radio frequency module 100 according to Embodiment 1 will be described with reference to FIG. 1. The radio frequency module 100 is used by being mounted on, for example, a communication unit (not illustrated). The radio frequency module 100 is a module that amplifies a transmission signal (balanced signal) from a signal processing circuit (not illustrated) included in the communication unit, performs balanced-unbalanced conversion, performs conversion into a signal having a predetermined frequency band, and causes a resulting signal to be transmitted outside from an antenna included in the communication unit. In Embodiment 1, the radio frequency module has only a function of processing a transmission signal, but may have a function of processing a reception signal received by the antenna.

The radio frequency module 100 amplifies input balanced signals S1 and S2 to perform conversion into unbalanced signals, and further performs impedance matching to output an unbalanced signal S3.

The radio frequency module 100 includes a first power amplifier PA1, a second power amplifier PA2, a transformer 1, a matching circuit 3, and a plurality of (four in the example of FIG. 1) external connection terminals 4 (4a to 4d).

The plurality of external connection terminals 4 include a first input terminal 4a, a second input terminal 4b, an output terminal 4c, and a power supply terminal 4d. The first input terminal 4a is a terminal which is connected to the first power amplifier PA1 and to which one (the first balanced signal S1) of two balanced signals (the first balanced signal S1 and the second balanced signal S2) to be input to the radio frequency module 100 is input. The second input terminal 4b is a terminal which is connected to the second power amplifier PA2 and to which the other one (the second balanced signal S2) of the two balanced signals is input. The output terminal 4c is a terminal which is connected to an unbalanced end (a third end 7a which will be described later) of the transformer 1 and outputs the unbalanced signal S3 obtained by performing balanced-unbalanced conversion on the signals by the transformer 1. The power supply terminal 4d is a terminal that is connected to an external power supply circuit (not illustrated) and supplies DC power to the first power amplifier PA1 and the second power amplifier PA2 with the transformer 1 interposed therebetween.

The first power amplifier PA1 is an amplifier that amplifies one signal (the first balanced signal S1) of the two balanced signals (the first balanced signal S1 and the second balanced signal S2). The first power amplifier PA1 has an input section and an output section. The input section of the first power amplifier PA1 is connected to the first input terminal 4a. The output section of the first power amplifier PA1 is connected to a first end 6a of a balanced side coil 6 of the transformer 1, which will be described later. As a result, a first amplified balanced signal amplified by the first power amplifier PA1 is input to the first end 6a of the balanced side coil 6.

The second power amplifier PA2 is an amplifier that amplifies the other signal the (second balanced signal S2) of the two balanced signals. The second power amplifier PA2 has an input section and an output section. The input section of the second power amplifier PA2 is connected to the second input terminal 4b. The output section of the second power amplifier PA2 is connected to a second end 6b of the balanced side coil 6 of the transformer 1, which will be described later. As a result, a second amplified balanced signal amplified by the second power amplifier PA2 is input to the second end 6b of the balanced side coil 6.

The transformer 1 combines the first amplified balanced signal input to the first end 6a and the second amplified balanced signal input to the second end 6b to convert the combined signal into an amplified unbalanced signal, and outputs the amplified unbalanced signal obtained through the conversion from a third end 7a of the transformer 1, which will be described later. The amplified unbalanced signal is output as the unbalanced signal S3 from the output terminal 4c with the matching circuit 3 interposed therebetween.

The transformer 1 includes the balanced side coil 6, an unbalanced side coil 7, an external connection wiring pattern portion 8, and a capacitor C2.

The balanced side coil 6 is used as a primary coil of the transformer 1 in Embodiment 1. The balanced side coil 6 has a coil conductor that is a circulated linear conductor. The balanced side coil 6 has a first end 6a, a second end 6b, and an intermediate tap 6c. The first end 6a is an input end which is one end of the coil conductor in a peripheral direction and to which the first amplified balanced signal is input. The first end 6a is connected to the output section of the first power amplifier PA1. That is, the first end 6a is connected to the first input terminal 4a with the first power amplifier PA1 interposed therebetween. The second end 6b is the other end of the coil conductor in the peripheral direction and is an input end to which the second amplified balanced signal is input. The second end 6b is connected to the output section of the second power amplifier PA2. That is, the second end 6b is connected to the second input terminal 4b with the first power amplifier PA1 interposed therebetween. The intermediate tap 6c is a part that is virtually electrically grounded between the first end 6a and the second end 6b in the coil conductor, and is an input section to which DC power is input from an external power supply circuit (not illustrated). The intermediate tap 6c is connected to the power supply circuit with the wiring pattern portion 8 and the power supply terminal 4d interposed therebetween.

The unbalanced side coil 7 is used as a secondary coil of the transformer 1 in Embodiment 1. The unbalanced side coil 7 is electromagnetically coupled to the balanced side coil 6. The unbalanced side coil 7 has a coil conductor that is a circulated linear conductor. The unbalanced side coil 7 has a third end 7a and a fourth end 7b. The third end 7a is one end of the coil conductor in the peripheral direction, and is an output end from which the amplified unbalanced signal is output. Hereinafter, the third end 7a may be described as an unbalanced end 7a. The third end 7a is connected to the matching circuit 3. That is, the third end 7a is connected to the output terminal 4c with the matching circuit 3 interposed therebetween. The fourth end 7b is the other end of the coil conductor in the peripheral direction and is connected to the ground. That is, the fourth end 7b is grounded.

The wiring pattern portion 8 is electrically connected to the intermediate tap 6c of the balanced side coil 6, and configures a wiring for electrically coupling the power supply circuit and the intermediate tap 6c.

A capacitor C1 (second capacitor) is connected between the first end 6a and the second end 6b of the balanced side coil 6. That is, the capacitor C1 is connected in parallel to the balanced side coil 6. The capacitor C1 removes a radio frequency noise component included in the balanced signals (the first balanced signal S1 and the second balanced signal S2) input to the first end 6a and the second end 6b of the balanced side coil 6. The capacitor C1 is not an essential component of the radio frequency module.

The capacitor C2 is connected between the intermediate tap 6c of the balanced side coil 6 and the ground. The capacitor C2 is a bypass capacitor that removes a radio frequency noise component included in DC power input from the power supply circuit to the intermediate tap 6c.

The matching circuit 3 is a circuit that matches the signal output from the unbalanced end 7a of the transformer 1 with the impedance of a predetermined circuit connected to the output terminal 4c. The matching circuit 3 has, for example, a capacitor C3 and inductors L21 and L22. The capacitor C3 and the inductor L21 are connected in series between the third end 7a of the unbalanced side coil 7 and the output terminal 4c. The inductor L22 is connected between the connection point of the capacitor C3 and the inductor L21 and the ground.

In Embodiment 1, the matching circuit 3 performs impedance matching between the first power amplifier PA1 and the second power amplifier PA2 and a predetermined circuit (for example, a filter) electrically connected to the output terminal 4c, but the impedance matching may be performed while including the transformer 1. Further, the impedance matching may be performed by only the transformer 1 and the matching circuit 3 may be omitted.

In the radio frequency module 100, assuming the first amplified balanced signal and the second amplified balanced signal of the first power amplifier PA1 and the second power amplifier PA2 are respectively input to the first end 6a and the second end 6b of the balanced side coil 6, a magnetic field occurs in the balanced side coil 6, and the magnetic field causes magnetic field coupling between the balanced side coil 6 and the unbalanced side coil 7, so that a voltage is induced in the unbalanced side coil 7 and the amplified unbalanced signal is output from the third end 7a of the unbalanced side coil 7. The unbalanced signal S3 is output from the output terminal 4c with the matching circuit 3 interposed therebetween.

### (2) Coil Structure of Transformer 1

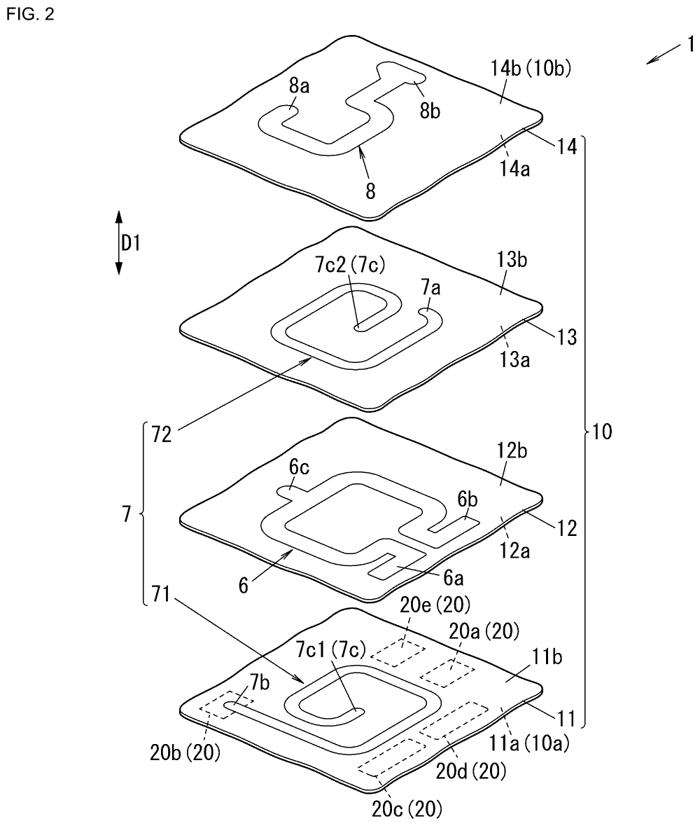

The coil structure of the transformer 1 (respective structures of the balanced side coil 6, the unbalanced side coil 7, and the wiring pattern portion 8) will be described with reference to FIGS. 2 to 7.

As shown in FIGS. 2 to 7, a first direction X1, a second direction X2, a third direction Y1, and a fourth direction Y2 are defined. The first to fourth directions X1, X2, Y1, and Y2 are directions parallel to first main surfaces 11a to 14a and second main surfaces 11b to 14b of dielectric layers 11 to 14. The second direction X2 is a direction opposite to the first direction X1. The third direction Y1 is a direction orthogonal to the first direction X1. The fourth direction Y2 is a direction opposite to the third direction Y1.

As shown in FIG. 2, the transformer 1 includes a multilayer substrate 10 and a plurality of external connection electrodes 20.

The multilayer substrate 10 is a substrate on which the balanced side coil 6, the unbalanced side coil 7, the wiring pattern portion 8, and the plurality of external connection electrodes 20 are disposed. The multilayer substrate 10 has a plurality of (for example, four) dielectric layers 11 to 14. The multilayer substrate 10 has a first main surface 10a and a second main surface 10b on both sides in the thickness direction D1. The plurality of dielectric layers 11 to 14 respectively have the first main surface 11a to 14a and the second main surface 11b to 14b on both sides in the thickness direction D1. The first main surfaces 11a to 14a are main surfaces of the dielectric layers 11 to 14 on the side of the first main surface 10a of the multilayer substrate 10. The second main surfaces 11b to 14b are main surfaces of the dielectric layers 11 to 14 on the side of the second main surface 10b of the multilayer substrate 10. The plurality of dielectric layers 11 to 14 are stacked in order from the side of the first main surface 10a of the multilayer substrate 10 toward the side of the second main surface 10b in the thickness direction D1 of the multilayer substrate 10. The first main surface 10a of the multilayer substrate 10 is the first main surface 11a of the dielectric layer 11, and the second main surface 10b of the multilayer substrate 10 is the second main surface 14b of the dielectric layer 14. Hereinafter, assuming the dielectric layers 11 to 14 are distinguished, the dielectric layers 11 to 14 are described as first to fourth dielectric layers 11 to 14.

The plurality of dielectric layers 11 to 14 include the balanced side coil 6, the unbalanced side coil 7, the wiring pattern portion 8, via conductors for electrically connecting the plurality of external connection electrodes 20, and the wiring pattern portion.

The plurality of external connection electrodes 20 (20a to 20e) are electrodes for connecting an external circuit board, and are disposed on the first main surface 10a of the multilayer substrate 10. The external connection electrode 20a is electrically connected to the third end 7a of a second unbalanced side coil portion 72 with a via conductor and a wiring pattern portion (not illustrated) interposed therebetween. The external connection electrode 20b is electrically connected to the fourth end 7b of a first unbalanced side coil portion 71 with a via conductor (not illustrated) interposed therebetween. The external connection electrodes 20c and 20d are electrically connected to the first end 6a and the second end 6b of the balanced side coil 6, respectively, with via conductors (not illustrated) interposed therebetween. The external connection electrode 20e is electrically connected to one end 8b of the wiring pattern portion 8 with a via conductor (not illustrated) interposed therebetween.

The balanced side coil 6, the unbalanced side coil 7, and the wiring pattern portion 8 are included in dielectric layers different from each other in the plurality of dielectric layers 11 to 14, and are disposed to overlap each other in the thickness direction D1 of the multilayer substrate 10.

More specifically, the unbalanced side coil 7 has the first unbalanced side coil portion 71 and the second unbalanced side coil portion 72. The first unbalanced side coil portion 71 is a part of the unbalanced side coil 7 between the fourth end 7b and a divided end portion 7c1. The second unbalanced side coil portion 72 is a part between a divided end portion 7c2 and the third end 7a. Each of the divided end portions 7cl and 7c2 is a divided end portion obtained assuming the unbalanced side coil 7 illustrated in FIG. 1 is divided into the first unbalanced side coil portion 71 and the second unbalanced side coil portion at a position 7c. The divided end portions 7cl and 7c2 are end portions corresponding to the position 7c of the unbalanced side coil 7 in FIG. 1. The wiring lengths of the first unbalanced side coil portion 71 and the second unbalanced side coil portion 72 may be the same or different.

The first unbalanced side coil portion 71 and the second unbalanced side coil portion 72 are disposed in dielectric layers different from each other in the plurality of dielectric layers 11 to 14. That is, the balanced side coil 6, the first unbalanced side coil portion 71, the second unbalanced side coil portion 72, and the wiring pattern portion 8 are disposed on dielectric layers different from each other in the plurality of dielectric layers 11 to 14.

In Embodiment 1, the first unbalanced side coil portion 71 is disposed on the second main surface 11b of the first dielectric layer 11. The balanced side coil 6 is disposed on the second main surface 12b of the second dielectric layer 12. The second unbalanced side coil portion 72 is disposed on the second main surface 13b of the third dielectric layer 13. The wiring pattern portion 8 is disposed on the second main surface 14b of the fourth dielectric layer 14. In other words, the first unbalanced side coil portion 71 is disposed on the side of the first main surface 10a of the multilayer substrate 10 in the balanced side coil 6. The second unbalanced side coil portion 72 is disposed on the side of the second main surface 10b of the multilayer substrate 10 in the balanced side coil 6. The wiring pattern portion 8 is disposed on the side of the second main surface 10b of the multilayer substrate 10 in the second unbalanced side coil portion 72.

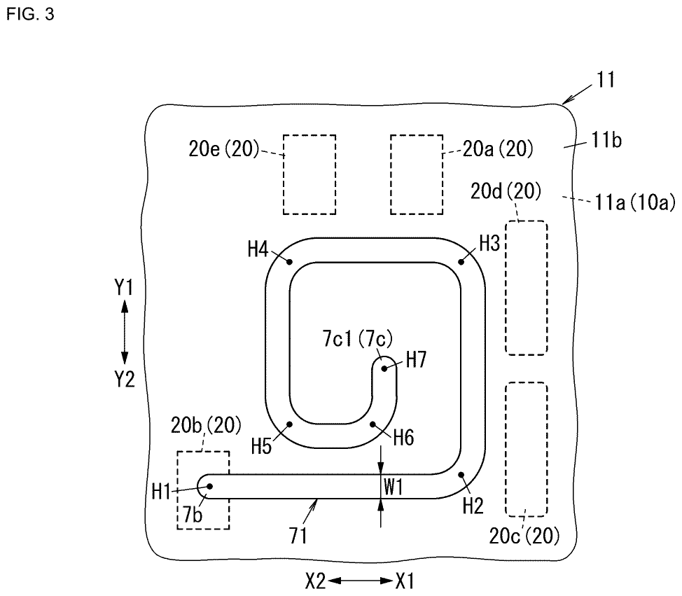

As illustrated in FIG. 3, the first unbalanced side coil portion 71 is formed in a circumferential shape (that is, helical shape) on the second main surface 11b of the first dielectric layer 11. One end of the first unbalanced side coil portion 71 is the fourth end 7b (see FIG. 1) of the unbalanced side coil 7, and the other end of the first unbalanced side coil portion 71 is the divided end portion 7cl corresponding to the position 7c of the unbalanced side coil 7 (see FIG. 1). More specifically, for example, the first unbalanced side coil portion 71 is formed to circulate around a predetermined area (for example, around the left) from the fourth end 7b in a helical shape.

More specifically, in the example of FIG. 3, the fourth end 7b is disposed at a predetermined position H1 (lower left position on the paper surface of FIG. 3), and the divided end portion 7cl is disposed at an end portion H7 in the circumference of the first unbalanced side coil portion 71. Hereinafter, the predetermined position H1 may be described as an end portion H1. The first unbalanced side coil portion 71 is formed to reach the end portion H7 from the end portion H1 through each of positions H2 to H6. The position H2 is a position in the first direction X1 assuming viewed from the end portion H1. The position H3 is a position in the third direction Y1 assuming viewed from the position H2.

The position H4 is a position in the second direction X2 assuming viewed from the position H3. The position H5 is a position in the fourth direction Y2 assuming viewed from the position H4. The position H6 is a position in the first direction X1 assuming viewed from the position H5. The end portion H7 is a position in the third direction Y1 assuming viewed from the position H6. The distance between the two positions H3 and H4 is shorter than the distance between the end portion H1 and the position H2. The distance between the two positions H4 and H5 is shorter than the distance between the two positions H2 and H3. The distance between the two positions H5 and H6 is shorter than the distance between the two positions H3 and H4. The distance between the position H6 and the end portion H7 is shorter than the distance between the two positions H4 and H5. In the example illustrated in FIG. 3, the first unbalanced side coil portion 71 is circulated, for example, in a quadrangle shape.

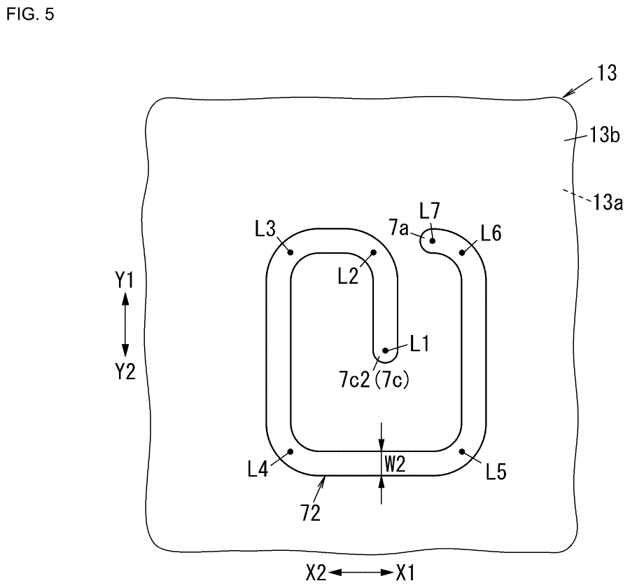

The fourth end 7b of the first unbalanced side coil portion 71 is electrically connected to the external connection electrode 20b with a via conductor (not illustrated) interposed therebetween. The divided end portion 7cl of the first unbalanced side coil portion 71 is connected to the divided end portion 7c2 (see FIG. 5) of the second unbalanced side coil portion 72 with a via conductor (not illustrated) interposed therebetween.

As illustrated in FIG. 5, the second unbalanced side coil portion 72 is formed in a circumferential shape (that is, helical shape) on the second main surface 13b of the third dielectric layer 13. One end of the second unbalanced side coil portion 72 is the divided end portion 7c2 corresponding to the position 7c (see FIG. 1) of the unbalanced side coil 7. The other end of the second unbalanced side coil portion 72 is the third end 7a (see FIG. 1) of the unbalanced side coil 7.

More specifically, the second unbalanced side coil portion 72 is formed to circulate around a predetermined area (for example, around the left) from the divided end portion 7c2 in a helical shape. In the example of FIG. 5, the divided end portion 7c2 is disposed at an end portion L1 in the circumference of the second unbalanced side coil portion 72, and the third end 7a is disposed at an end portion L7 (upper right position on the paper surface of FIG. 5). The second unbalanced side coil portion 72 is formed to reach the end portion L7 from the end portion L1 through positions L2 to L6.

The position L2 is a position in the third direction Y1 assuming viewed from the end portion L1. The position L3 is a position in the second direction X2 assuming viewed from the position L2. The position L4 is a position in the fourth direction Y2 assuming viewed from the position L3. The position L5 is a position in the first direction X1 assuming viewed from the position L4. The position L6 is a position in the third direction Y1 assuming viewed from the position L5. The end portion L7 is a position in the second direction X2 assuming viewed from the position L6. The distance between the two positions L3 and L4 is longer than the distance between the end portion L1 and the position L2. For example, the distance between the two positions L3 and L4 is approximately twice as long as the distance between the end portion L1 and the position L2. The distance between the two positions L4 and L5 is longer than the distance between the two positions L2 and L3. For example, the distance between the two positions L4 and L5 is approximately twice as long as the distance between the two positions L2 and L3. The distance between the two positions L5 and L6 is, for example, the same as the distance between the two positions L3 and L4. The distance between the position L6 and the end portion L7 is shorter than the distance between the two positions L2 and L3. In the example illustrated in FIG. 5, the second unbalanced side coil portion 72 is circulated, for example, in a quadrangle shape. The second unbalanced side coil portion 72 is circulated such that at least a part thereof overlaps the first unbalanced side coil portion 71 in the circumference direction (that is, the wiring length direction) in a plan view from the thickness direction D1.

The divided end portion 7c2 of the second unbalanced side coil portion 72 is electrically connected to the divided end portion 7c1 (see FIG. 3) of the first unbalanced side coil portion 71 with a via conductor (not illustrated) interposed therebetween. The third end 7a of the second unbalanced side coil portion 72 is electrically connected to the external connection electrode 20a with a via conductor and the wiring pattern portion interposed therebetween.

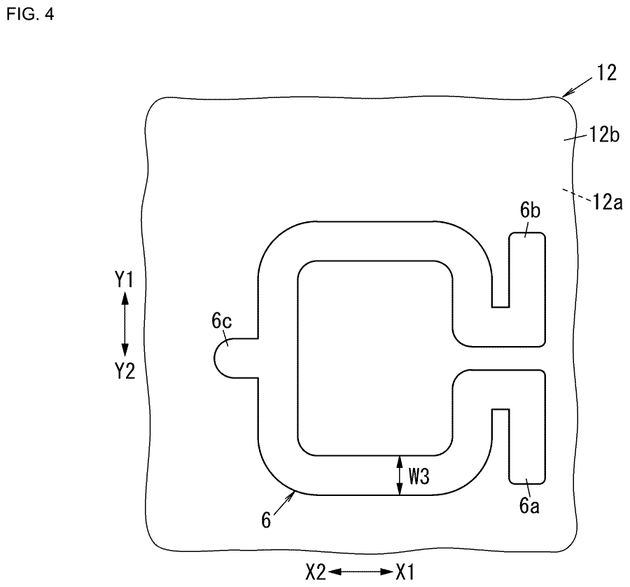

As illustrated in FIG. 4, for example, the balanced side coil 6 is formed to circulate once on the second main surface 12b of the second dielectric layer 12. The first end 6a, the second end 6b, and the intermediate tap 6c are extended to the outer peripheral side. More specifically, in the example of FIG. 4, the balanced side coil 6 is circulated, for example, in a C shape (a quadrangle C shape in the example of FIG. 4). The first end 6a and the second end 6b are respectively extended in the first direction X1. The first end 6a and the second end 6b are electrically connected to the external connection electrodes 20c and 20d, respectively, with via conductors interposed therebetween. The intermediate tap 6c is extended in the second direction X2 from a position of the balanced side coil 6, which is electrically virtually grounded. The intermediate tap 6c is connected to one end 8a of the wiring pattern portion 8 with a via conductor interposed therebetween.

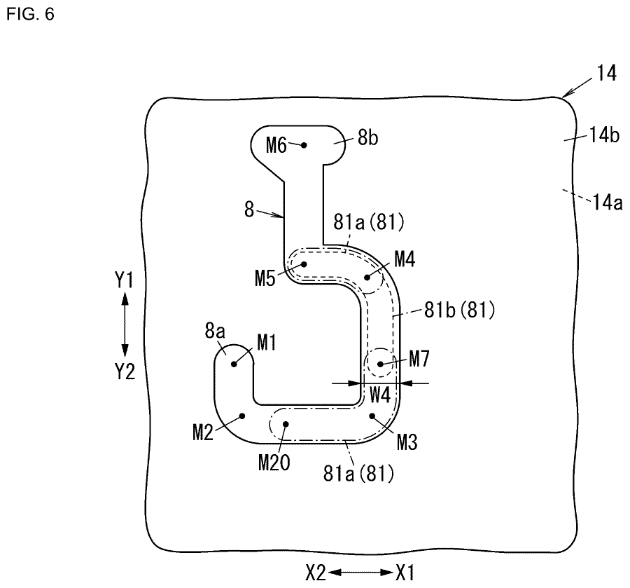

As illustrated in FIG. 6, the wiring pattern portion 8 is formed to circulate to overlap at least a part in the peripheral direction of the unbalanced side coil 7 from the end portion M1 that overlaps the intermediate tap 6c (see FIG. 4) of the balanced side coil 6 to a predetermined extended position (end portion M6) on the second main surface 14b of the fourth dielectric layer 14 in a plan view from the thickness direction D1.

More specifically, the wiring pattern portion 8 is formed on the second main surface 14b of the fourth dielectric layer 14 to reach the end portion M6 from the end portion M1 through each of the positions M2, M3, M4, and M5. As described above, the end portion M1 is a position that overlaps the intermediate tap 6c of the balanced side coil 6. For example, the end portion M6 is a position at an edge portion on the second main surface 14b of the fourth dielectric layer 14 in the third direction Y1. The position M2 is a position in the fourth direction Y2 assuming viewed from the end portion M1. The position M3 is a position in the first direction X1 assuming viewed from the position M2. The position M4 is a position in the third direction Y1 assuming viewed from the position M3. The position M5 is a position in the second direction X2 assuming viewed from the position M4 and in the fourth direction Y2 assuming viewed from the end portion M6. The distance between the two positions M3 and M4 is longer than the distance between the end portion M1 and the position M2. For example, the distance between the two positions M3 and M4 is twice as long as the distance between the end portion M1 and the position M2. The distance between the two positions M4 and M5 is shorter than the distance between the two positions M2 and M3. For example, the distance between the two positions M4 and M5 is half the distance between the two positions M2 and M3.

In Embodiment 1, the wiring pattern portion 8 is formed to have, for example, a curved part curved in a loop shape (or an arc shape). More specifically, the wiring pattern portion 8 extends in the fourth direction Y2 from the end portion M1 to the position M2, and circulates around a predetermined area (for example, around the left) to reach the position M5. The wiring pattern portion 8 extends in the third direction Y1 from the position M5 to the end portion M6.

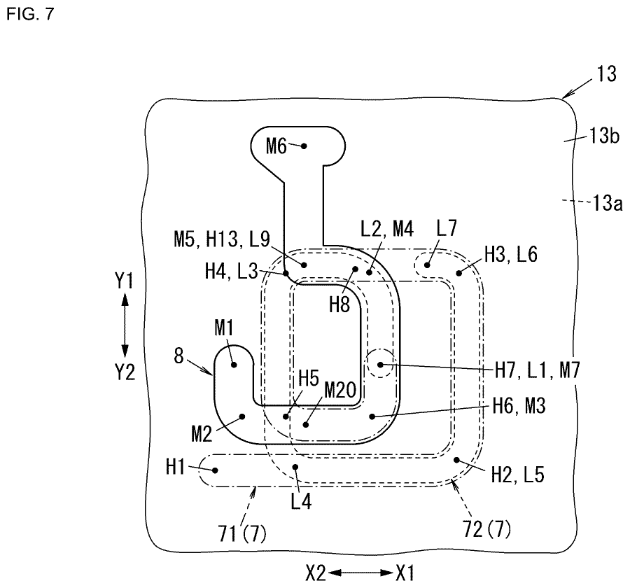

As illustrated in FIG. 6, the wiring pattern portion 8 has an overlapping portion 81 that overlaps the unbalanced side coil 7 (the first unbalanced side coil portion 71 and the second unbalanced side coil portion 72 (see FIG. 7)) along the peripheral direction in a plan view from the thickness direction D1. In Embodiment 1, the wiring pattern portion 8 is used as a part of the balanced side coil 6, and the electromagnetic coupling between the balanced side coil 6 and the unbalanced side coil 7 is strengthened by the overlapping portion 81 of the wiring pattern portion 8, so that the coupling coefficient of the transformer 1 is increased.

More specifically, as illustrated in FIG. 6, the overlapping portion 81 includes a part along the positions M20, M3, M4, and M5 of the wiring pattern portion 8. The overlapping portion 81 has a first overlapping portion 81a and a second overlapping portion 81b. The first overlapping portion 81a is a part that overlaps the first unbalanced side coil portion 71 in a plan view from the thickness direction D1. The first overlapping portion 81a includes a part along the positions M4 and M5 and a part along the positions M20, M3, and M7 in the wiring pattern portion 8. The position M20 is a position in the first direction X1 assuming viewed from the position 2 in the wiring pattern portion 8. The position M7 is a position in the first direction X1 assuming viewed from the end portion M1 in the wiring pattern portion 8. The second overlapping portion 81b is a part that overlaps the second unbalanced side coil portion 72 in a plan view from the thickness direction D1. The second overlapping portion 81b includes a part along the positions M7, M4, and M5 of the wiring pattern portion 8.

As illustrated in FIG. 7, the first overlapping portion 81a (a part along the positions M4 and M5 and a part along the positions M20, M3, and M7) overlaps a part along positions H8 and H13 and a part along the positions H5, H6, and H7 in the first unbalanced side coil portion 71. The position H8 is a position in the third direction Y1 assuming viewed from the end portion H7 in the first unbalanced side coil portion 71. The position H13 is a position between the positions H4 and H8 in the first unbalanced side coil portion 71. The second overlapping portion 81b (a part along the positions M7, M4, and M5) overlaps a part along the end portion L1, the position L2, and the position L9 of the second unbalanced side coil portion 72. The position L9 is a position between the positions L2 and L3 in the second unbalanced side coil portion 72.

The first overlapping portion 81a and the second overlapping portion 81b are regions different from each other in the thickness direction D1. The “regions different from each other” means that at least one overlapping portion of the first overlapping portion 81a and the second overlapping portion 81b has a region that does not overlap the other overlapping portion in a plan view from the thickness direction D1. Accordingly, it is possible to suppress the mutual interference in the magnetic field coupling between the first overlapping portion 81a and the first unbalanced side coil portion 71 and the magnetic field coupling between the second overlapping portion 81b and the second unbalanced side coil portion 72. Accordingly, the wiring pattern portion 8 can realize stronger magnetic field coupling with both the first unbalanced side coil portion 71 and the second unbalanced side coil portion 72.

Next, the relationship between the line widths W1 to W4 of the first unbalanced side coil portion 71, the second unbalanced side coil portion 72, the balanced side coil 6, and the wiring pattern portion 8 will be described. The line widths W1 to W4 are line widths viewed in a plan view from the thickness direction D1. For example, the line width W1 of the first unbalanced side coil portion 71 and the line width of the second unbalanced side coil portion 72 are narrower than the line width W3 of the balanced side coil 6 and the line width W4 of the wiring pattern portion 8. Accordingly, even though the dielectric layers on which the balanced side coil 6, the first unbalanced side coil portion 71, and the second unbalanced side coil portion 72 are formed are stacked with deviations from each other in a direction parallel to the main surface of the multilayer substrate 10 assuming the transformer 1 is manufactured, the positional deviation between wirings to be combined can be tolerated to some extent due to the differences in the line width. Therefore, change in the coupling coefficient of the transformer 1 with respect to the deviations can be suppressed. Since the same effect can be obtained assuming the line widths of the wirings to be combined are different, in such a configuration, the line widths of the first unbalanced side coil portion 71 and the second unbalanced side coil portion 72 may be different. For example, the relationship between the line widths W1 to W4, W1<W2<W3<W4 or, conversely, W1>W2>W3>W4 may be satisfied. Further, W1=W2<W3=W4 or W1=W2>W3=W4 may be satisfied.

For example, assuming the line width W3 of the balanced side coil 6 is larger than the line width W1 of the first unbalanced side coil portion 71, the electric resistance of the balanced side coil 6 can be made smaller than the electric resistance of the unbalanced side coil 7. Accordingly, assuming the output sections of the first power amplifier PA1 and the second power amplifier PA2 are respectively connected to the first end 6a and the second end 6b of the balanced side coil 6, loss due to the electric resistance of each of the outputs of the first power amplifier PA1 and the second power amplifier PA2 can be reduced.

### (3) Comparative Example

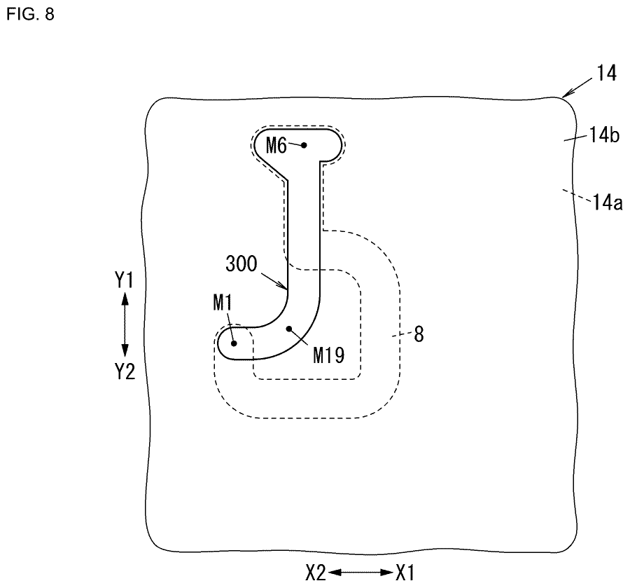

A wiring pattern portion 300 of Comparative Example will be described with reference to FIG. 8.

The wiring pattern portion 300 is formed to reach the end portion M6 from the end portion M1 through the position M19 in a plan view from the thickness direction D1 of the multilayer substrate 10. The position M19 is a position in the first direction X1 assuming viewed from the end portion M1 and is a position in the fourth direction Y2 assuming viewed from the end portion M6. In this case, the wiring pattern portion 300 overlaps the unbalanced side coil 7 and intersects the unbalanced side coil 7 in a plan view from the thickness direction D1 of the multilayer substrate 10, but does not overlap the unbalanced side coil 7 along the peripheral direction as in the wiring pattern portion 8 of Embodiment 1. Therefore, the wiring pattern portion 300 of the comparative example has weaker magnetic field coupling with the unbalanced side coil 7 than the wiring pattern portion 8 of Embodiment 1. Therefore, even assuming the wiring pattern portion 300 of the comparative example is used as a part of the balanced side coil 6, the coupling coefficient of the transformer 1 cannot be increased as in the case of Embodiment 1.

### (4) Effects

As described above, the transformer 1 according to Embodiment 1 includes the balanced side coil 6, the unbalanced side coil 7, the external connection wiring pattern portion 8, and the multilayer substrate 10. The balanced side coil 6 has the first end 6a, the second end 6b, and the intermediate tap 6c included between the first end 6a and the second end 6b. The unbalanced side coil 7 has the third end 7a and the fourth end 7b. The fourth end 7b is grounded. The wiring pattern portion 8 is electrically connected to the intermediate tap 6c. The multilayer substrate 10 includes the plurality of dielectric layers 11 to 14, and the balanced side coil 6, the unbalanced side coil 7, and the wiring pattern portion 8 in layers different from each other in the plurality of dielectric layers 11 to 14. The balanced side coil 6 and the unbalanced side coil 7 at least partially overlap each other in a plan view from the thickness direction D1 of the multilayer substrate 10. The wiring pattern portion 8 has the overlapping portion 81 that overlaps the unbalanced side coil 7 along the peripheral direction in a plan view from the thickness direction D1 of the multilayer substrate 10. That is, the overlapping portion 81 overlaps the unbalanced side coil 7 in the thickness direction D1 of the multilayer substrate 10, and is disposed along the peripheral direction of the multilayer substrate 10 in a plan view from the thickness direction D1 of the multilayer substrate 10.

According to this configuration, the wiring pattern portion 8 has the overlapping portion 81 that overlaps the unbalanced side coil 7 along the peripheral direction in a plan view from the thickness direction D1 of the multilayer substrate 10. Accordingly, the electromagnetic coupling between the wiring pattern portion 8 and the unbalanced side coil 7 can be strengthened by using the wiring pattern portion 8 (especially the overlapping portion 81) as a part of the balanced side coil 6. As a result, the coupling coefficient of the transformer 1 can be increased. In this configuration, in order to increase the coupling coefficient of the transformer 1, the number of turns need not be increased or the line width need not be narrowed in the line width in the balanced side coil 6 and the unbalanced side coil 7. Therefore, the increase in size of the transformer 1 and a signal loss in the transformer 1 can be suppressed. As above, the coupling coefficient of the transformer 1 can be made larger by suppressing the increase in size of the transformer 1 and the signal loss in the transformer 1.

Further, since the overlapping portion 81 overlaps the unbalanced side coil 7 along the peripheral direction in a plan view from the thickness direction of the multilayer substrate 10, the wiring pattern portion 8 is formed so as not to intersect a central part (a part where the magnetic fields generated by the balanced side coil 6 and the unbalanced side coil 7 are concentrated) of each of the cavities of the balanced side coil 6 and the unbalanced side coil 7. Therefore, it is possible to suppress the disturbance of the magnetic fields generated by the balanced side coil 6 and the unbalanced side coil 7. Accordingly, deterioration in the coupling state between the balanced side coil 6 and the unbalanced side coil 7 can be suppressed, and the coupling coefficient of the transformer 1 can be made larger.

Further, the radio frequency module 100 of Embodiment 1 includes the transformer 1, the first input terminal 4a, the second input terminal 4b, the first power amplifier PA1, and the second power amplifier PA2. The first power amplifier PA1 amplifies the first balanced signal S1 input from the first input terminal 4a, and outputs a resulting signal to the first end 6a of the transformer 1. The second power amplifier PA2 amplifies the second balanced signal S2 input from the second input terminal 4b, and outputs a resulting signal to the second end 6b of the transformer 1. According to this configuration, the radio frequency module 100 including the transformer 1 can be provided.

### (5) Modification Examples

Hereinafter, modification examples of the radio frequency module 100 of Embodiment 1 will be described. A combination of Embodiment 1 and the following modification examples may be implemented. In the following description, the same configurations as in the embodiment are attached with the same reference numerals and the description thereof is omitted, and only configurations different from the embodiment may be described.

(Modification Example 1) Modification Example 1 is a modification example of the wiring pattern portion 8 of Embodiment 1.

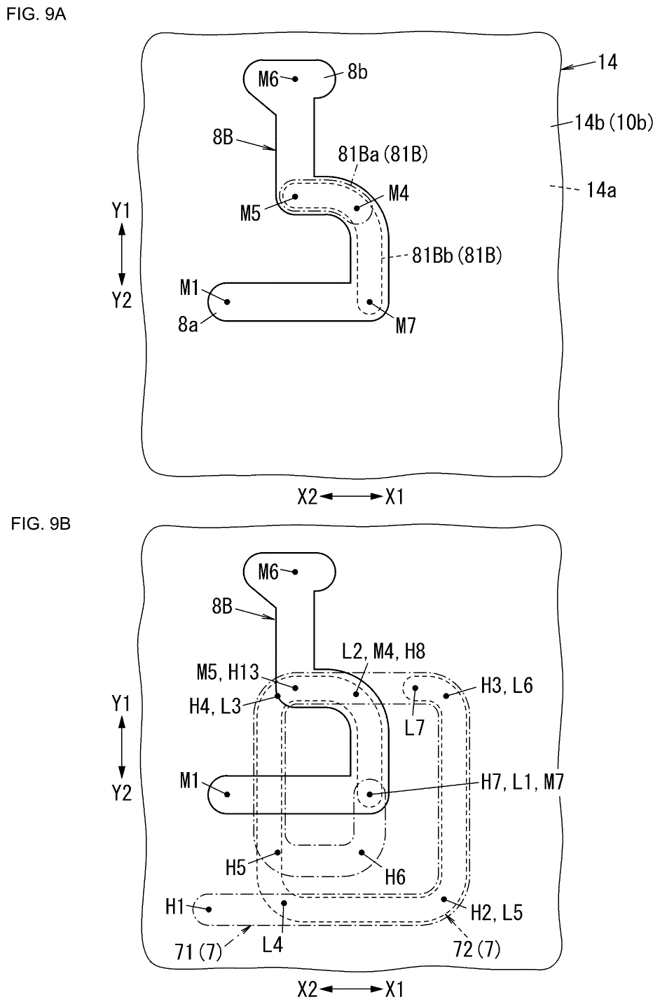

As illustrated in FIG. 9A, a wiring pattern portion 8B of Modification Example 1 is formed on the second main surface 14b of the fourth dielectric layer 14 to reach the end portion M6 from the end portion M1 through each of the positions M7, M4, and M5. The end portion M1, the position M4, the position M5, and the end portion M6 are the same positions as the end portion M1, the position M4, the position M5, and the end portion M6 in Embodiment 1. The position M7 is a position in the first direction X1 assuming viewed from the end portion M1, and is a position that overlaps the end portion H7 (see FIG. 3) of the first unbalanced side coil portion 71 in a plan view from the thickness direction D1. The position M4 is a position in the third direction Y1 assuming viewed from the position M7. The distance between the two positions M4 and M5 is shorter than the distance between the end portion M1 and the position M4. For example, the distance between the two positions M4 and M5 is half the distance between the end portion M1 and the position M4. That is, the wiring pattern portion 8B of Modification Example 1 extends in the first direction X1 from the end portion M1 to the position M7, and circulates around a predetermined area (for example, around the left) to reach the position M5. The wiring pattern portion 8B extends in the third direction Y1 from the position M5 to the end portion M6.

As illustrated in FIG. 9A, the wiring pattern portion 8B has an overlapping portion 81B that overlaps the unbalanced side coil 7 along the peripheral direction in a plan view from the thickness direction D1. The overlapping portion 81B includes a part along the positions M7, M4, and M5 of the wiring pattern portion 8B in a plan view from the thickness direction D1. The overlapping portion 81B has a first overlapping portion 81Ba and a second overlapping portion 81Bb. The overlapping portion 81B has a first overlapping portion 81Ba and a second overlapping portion 81Bb. The first overlapping portion 81Ba is a part that overlaps the first unbalanced side coil portion 71 in a plan view from the thickness direction D1, and includes a part along the positions M4 and M5 of the wiring pattern portion 8B. The second overlapping portion 81Bb is a part that overlaps the second unbalanced side coil portion 72 in a plan view from the thickness direction D1, and includes a part along the positions M7, M4, and M5 of the wiring pattern portion 8B.

As illustrated in FIG. 9B, the first overlapping portion 81Ba (a part along the positions M4 and M5) overlaps a part along the positions H8 and H13 of the first unbalanced side coil portion 71. The position H8 is a position in the third direction Y1 assuming viewed from the end portion H7 in the first unbalanced side coil portion 71. The position H13 is a position between the positions H8 and H4 in the first unbalanced side coil portion 71. The second overlapping portion 81Bb (a part along the positions M7, M4, and M5) overlaps a part along the end portion L1, the position L2, and the position L9 of the second unbalanced side coil portion 72. The position L9 is a position between the positions L2 and L3 in the second unbalanced side coil portion 72.

In Modification Example 1, similarly to the wiring pattern portion 8 of Embodiment 1, the wiring pattern portion 8B has the overlapping portion 81B, so that the electromagnetic coupling between the wiring pattern portion 8B and the unbalanced side coil 7 can be strengthened.

### Modification Example 2

Modification Example 2 is another modification example of the wiring pattern portion 8 of Embodiment 1.

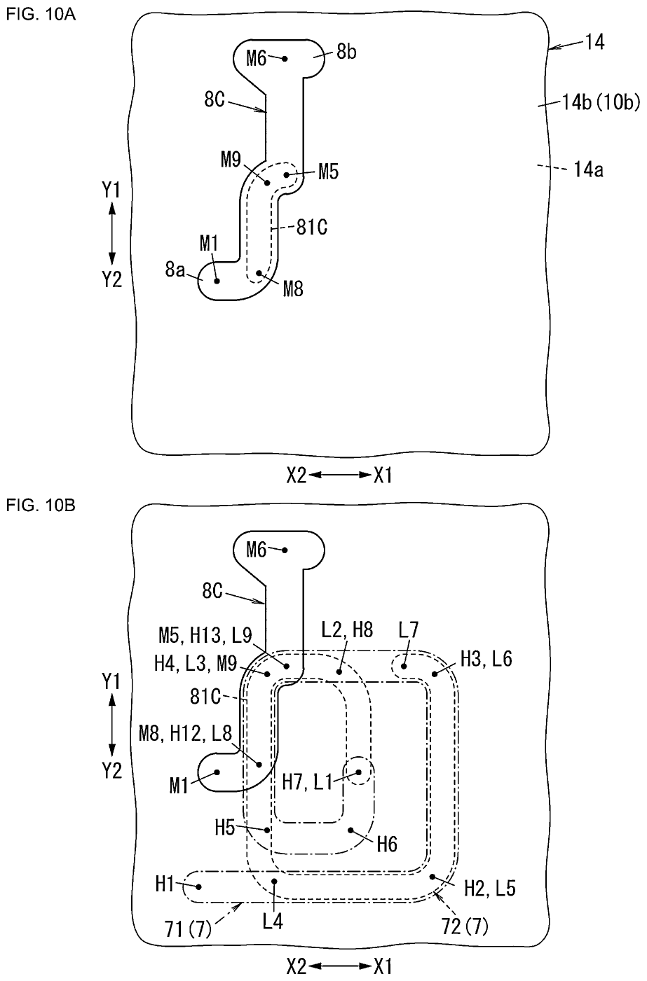

As illustrated in FIG. 10A, a wiring pattern portion 8C of Modification Example 2 is formed on the second main surface 14b assuming viewed from the fourth dielectric layer 14 to reach the end portion M6 from the end portion M1 through each of the positions M8, M9, and M5. The end portion M1, the position M5, and the end portion M6 are the same positions as the end portion M1, the position M5, and the end portion M6 of Embodiment 1. The position M8 is a position in the first direction X1 assuming viewed from the end portion M1. The position M9 is a position in the third direction Y1 assuming viewed from the position M8. The position M5 is a position in the first direction X1 assuming viewed from the position M9. That is, the wiring pattern portion 8C of Modification Example 2 extends a little in the first direction X1 from the end portion M1 to the position M8, and circulates around a predetermined area (for example, around the right) to reach the position M5. The wiring pattern portion 8C extends in the third direction Y1 from the position M5 to the end portion M6.

As illustrated in FIG. 10A, the wiring pattern portion 8C has an overlapping portion 81C that overlaps the unbalanced side coil 7 along the peripheral direction in a plan view from the thickness direction D1. The overlapping portion 81C includes a part along the positions M8, M9, and M5 of the wiring pattern portion 8C in a plan view from the thickness direction D1.

As illustrated in FIG. 10B, the overlapping portion 81C (a part along the positions M8, M9, and M5) overlaps a part along the H12, H4, and H13 of the first unbalanced side coil portion 71. The position H12 is a position in the second direction X2 assuming viewed from the end portion H7 in the first unbalanced side coil portion 71. The position H13 is the same as the position H13 of first modification example. Further, the overlapping portion 81C overlaps a part along the positions L8, L3, and L9 of the second unbalanced side coil portion 72. The position L8 is a position in the second direction X2 assuming viewed from the end portion L1 in the second unbalanced side coil portion 72. The position L9 is a position between the two positions L3 and L2 in the second unbalanced side coil portion 72.

In Modification Example 2, similarly to the wiring pattern portion 8 of Embodiment 1, the wiring pattern portion 8C has the overlapping portion 81C, so that the electromagnetic coupling between the wiring pattern portion 8 and the unbalanced side coil 7 can be strengthened.

### Modification Example 3

Modification Example 3 is another modification example of the wiring pattern portion 8 of Embodiment 1.

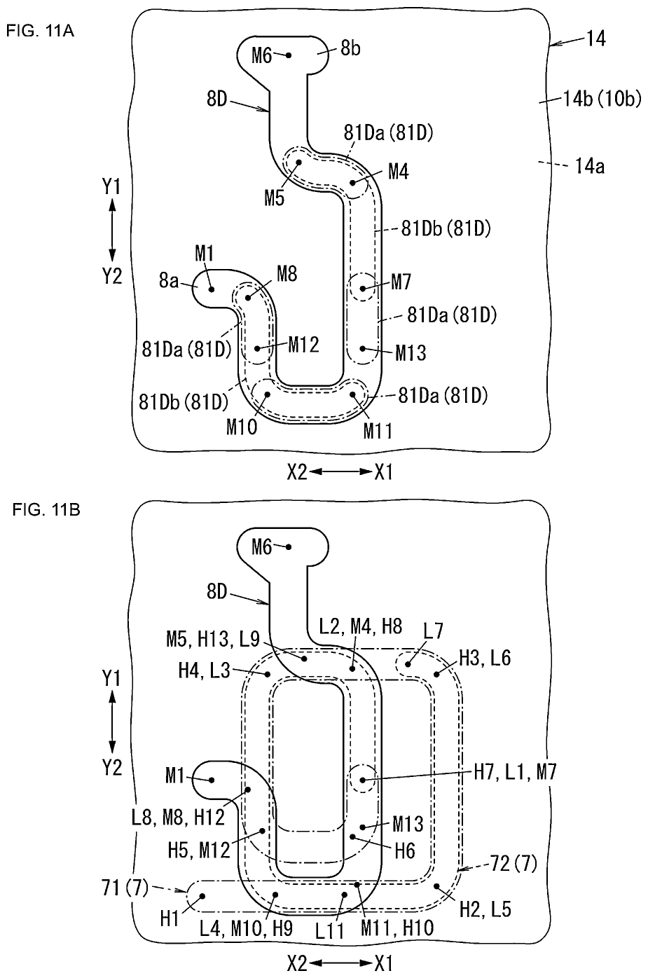

As illustrated in FIG. 11A, a wiring pattern portion 8D of Modification Example 3 is formed on the second main surface 14b of the fourth dielectric layer 14 to reach the end portion M6 from the end portion M1 through each of the positions M8, M10, M11, M4, and M5. The end portion M1, the position M4, the position M5, and the end portion M6 are the same positions as the end portion M1, the position M4, the position M5, and the end portion M6 in Embodiment 1. The position M8 is the same position as the position M8 of Modification Example 2. The position M10 is a position in the fourth direction Y2 assuming viewed from the position M8. The position M11 is a position in the first direction X1 assuming viewed from the position M10. The position M4 is a position in the third direction Y1 assuming viewed from the position M11. The position M5 is a position in the second direction X2 assuming viewed from the position M4. The distance between the two positions M11 and M4 is longer than the distance between the two positions M8 and M10. For example, the distance between the two positions M11 and M4 is twice the distance between the two positions M8 and M10.

That is, the wiring pattern portion 8D of Modification Example 3 extends in the first direction X1 from the end portion M1 to the position M8 and further extends in the fourth direction Y2 to the position M10, and circulates around a predetermined area (for example, around the left) to reach the position M5. The wiring pattern portion 8D extends in the third direction Y1 from the position M5 to the end portion M6. The distance between the two positions M8 and M10 is longer than the distance between the end portion M1 and the position M2 of the wiring pattern portion 8 of Embodiment 1. That is, the wiring pattern portion 8D of Modification Example 3 is longer in the fourth direction Y2 than the wiring pattern portion 8 of Embodiment 1.

As illustrated in FIG. 11A, the wiring pattern portion 8D has an overlapping portion 81D that overlaps the unbalanced side coil 7 along the peripheral direction in a plan view from the thickness direction D1. The overlapping portion 81D includes a part along the positions M8, M10, M11, M4, and M5 of the wiring pattern portion 8D in a plan view from the thickness direction D1.

The overlapping portion 81D has a first overlapping portion 81Da and a second overlapping portion 81Db.

The first overlapping portion 81Da is a part that overlaps the first unbalanced side coil portion 71 in a plan view from the thickness direction D1. The first overlapping portion 81Da includes a part along the positions M8 and M12, a part along the positions M10 and M11, along the positions M13 and M7, and along the positions M4 and M5 in the wiring pattern portion 8D. The position M8 is the same position as the position M8 of Modification Example 2. The position M12 is a position between the positions M8 and M10 in the wiring pattern portion 8D. The position M10 is a position in the fourth direction Y2 assuming viewed from the position M8 in the wiring pattern portion 8E. The position M11 is a position in the first direction X1 assuming viewed from the position M10. The position M13 is a position between the positions M11 and M7 in the wiring pattern portion 8D. The position M7 is a position in the first direction X1 assuming viewed from the position M8 in the wiring pattern portion 8D.

The second overlapping portion 81Db is a part that overlaps the second unbalanced side coil portion 72 in a plan view from the thickness direction D1. The second overlapping portion 81Db includes a part along the positions M8, M10, and M11 and a part along the positions M7, M4, and M5 in the wiring pattern portion 8D.

As illustrated in FIG. 11B, the first overlapping portion 81Da (a part along positions M8 and M12, a part along the positions M10 and M11, a part along the positions M13 and M7, and a part along the positions M4 and M5) overlaps a part along the positions H12 and H5, a part along the positions H9 and H10, a part along the positions H6 and H7, and a part along the positions H8 and H13 in the first unbalanced side coil portion 71. The position H12 is a position in the second direction X2 assuming viewed from the end portion H7 in the first unbalanced side coil portion 71. The positions H9 and H10 are positions in the fourth direction Y2 assuming viewed from the positions H5 and H6, respectively, in the first unbalanced side coil portion 71. The positions H8 and H13 are the same positions as the positions H8 and H13 of Embodiment 1.

The second overlapping portion 81Db (a part along the positions M8, M10, and M11 and a part along the positions M7, M4, and M5) overlaps a part along the positions L8, L4, and L11 and a part along the end portion L1, the position L2, and the position L9 in the second unbalanced side coil portion 72. The positions L8 and L9 are the same positions as the positions L8 and L9 of Modification Example 2. The position L11 is a position in the fourth direction Y2 assuming viewed from the end portion L1 in the second unbalanced side coil portion 72.

In Modification Example 3, similarly to the wiring pattern portion 8 of Embodiment 1, the wiring pattern portion 8D has the overlapping portion 81D, so that the electromagnetic coupling between the wiring pattern portion 8 and the unbalanced side coil 7 can be strengthened.

### Modification Example 4

Modification Example 4 is another modification example of the wiring pattern portion 8 of Embodiment 1.

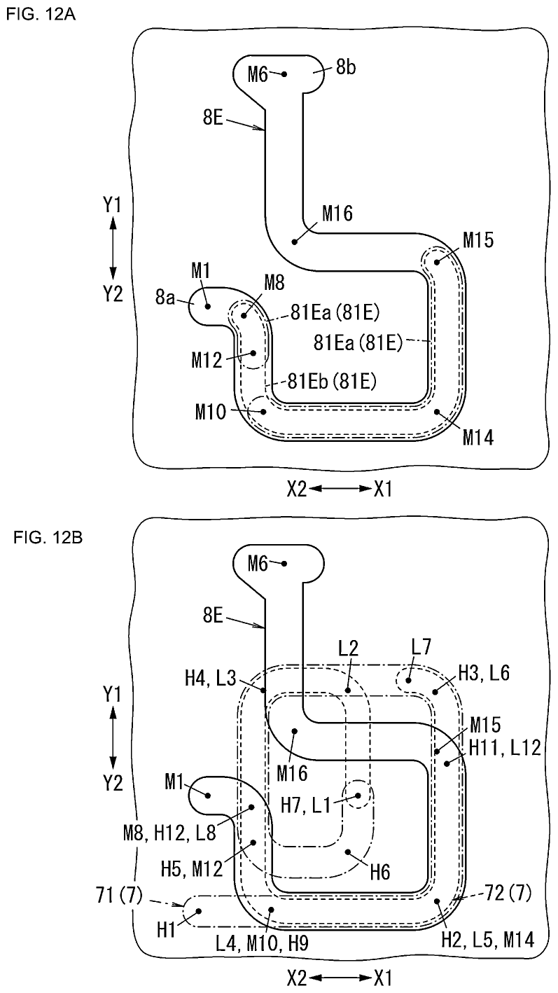

As illustrated in FIG. 12A, the wiring pattern portion 8E of Modification Example 4 is formed on the second main surface 14b of the fourth dielectric layer 14 to reach the end portion M6 from the end portion M1 through each of the positions M8, M10, M14, M15, and M16. The end portion M1, the position M8, the position M10, and the end portion M6 are the same positions as the end portion M1, the position M8, the position M10, and the end portion M6 of Modification Example 3. The position M14 is a position in the first direction X1 assuming viewed from the position M10. The position M15 is a position in the third direction Y1 assuming viewed from the position M14. The position M16 is a position in the second direction X2 assuming viewed from the position M15. The end portion M6 is a position in the third direction Y1 assuming viewed from the position M14. The distance between the two positions M13 and M14 is shorter than the distance between the two positions M10 and M12.

As illustrated in FIG. 12A, the wiring pattern portion 8E has an overlapping portion 81E that overlaps the unbalanced side coil 7 along the peripheral direction in a plan view from the thickness direction D1. The overlapping portion 81E has a first overlapping portion 81Ea and a second overlapping portion 81Eb.

The first overlapping portion 81Ea is a part that overlaps the first unbalanced side coil portion 71 in a plan view from the thickness direction D1, and includes a part along the positions M8 and M12 and a part along the positions M10, M14, and M15 in the wiring pattern portion 8E. The positions M8, M10, and M12 are the same positions as the positions M8, M10, and M12 of Modification Example 3. The position M14 is a position in the first direction X1 assuming viewed from the position M10 in the wiring pattern portion 8E. The position M15 is a position in the third direction Y1 assuming viewed from the position M14 in the wiring pattern portion 8E. The second overlapping portion 81Eb is a part that overlaps the second unbalanced side coil portion 72 in a plan view from the thickness direction D1, and includes a part along the positions M8, M10, M14, and M15 in the wiring pattern portion 8E.

As illustrated in FIG. 12B, the first overlapping portion 81Ea (a part along the positions M8 and M12 and a part along the positions M10, M14, and M15) overlaps a part along the positions H12 and M5 and a part along the positions H9, H2, and H11 in the first unbalanced side coil portion 71. The positions H12, H5, and H9 are the same positions as the positions H12, H5, and H9 of Modification Example 3. The position H11 is a position on the upper side of the end portion H7 between the positions H2 and H3 of the first unbalanced side coil portion 71. The second overlapping portion 81Eb (a part along the positions M8, M10, M14, and M15) overlaps a part along the positions L8, L4, L5, and L12 of the second unbalanced side coil portion 72. The position L8 is a position in the second unbalanced side coil portion 72 in the second direction X2 assuming viewed from the end portion L1. The position L12 is a position on the upper side of the end portion L1 between the positions H5 and H6 of the second unbalanced side coil portion 72.

In Modification Example 4, similarly to the wiring pattern portion 8 of Embodiment 1, the wiring pattern portion 8E has the overlapping portion 81E, so that the electromagnetic coupling between the wiring pattern portion 8 and the unbalanced side coil 7 can be strengthened.

### Modification Example 5

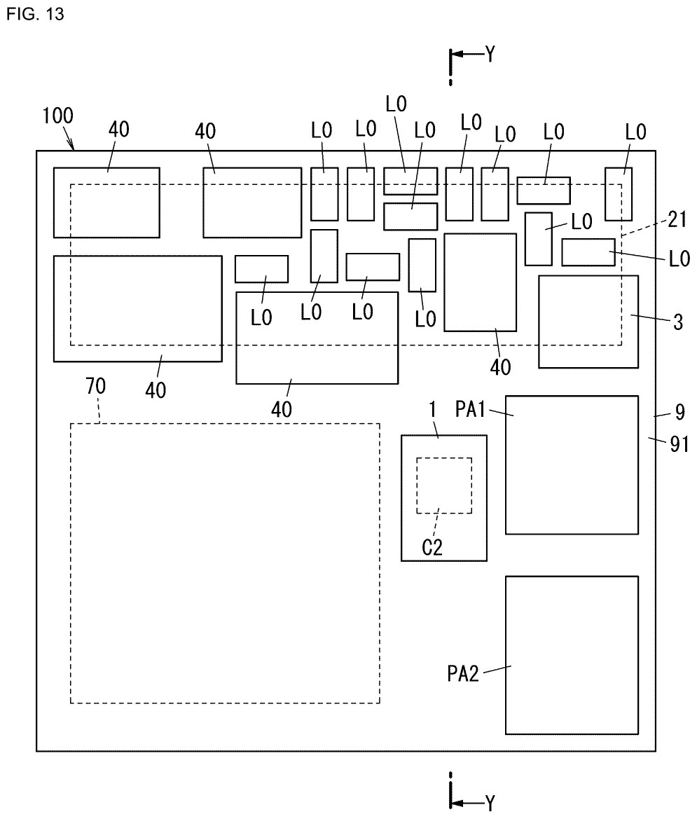

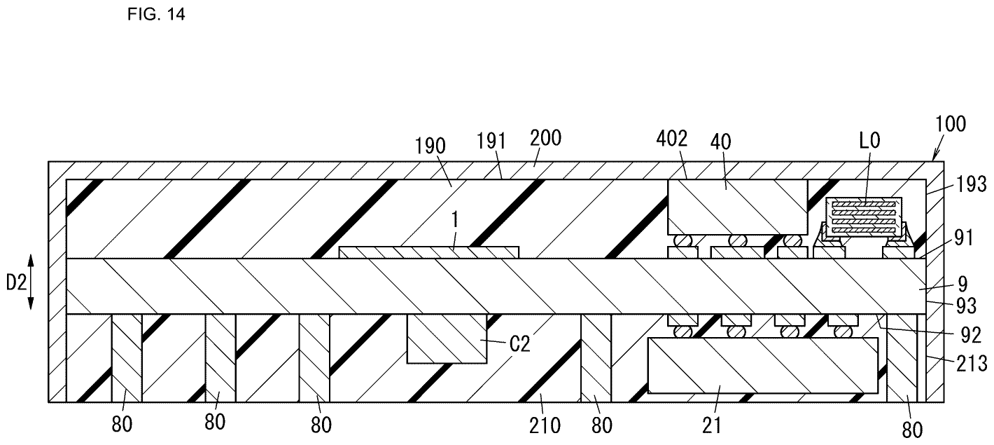

A radio frequency module 100 of Modification Example 5 will be described with reference to FIGS. 13 and 14. The radio frequency module 100 includes a mounting substrate 9, a plurality of transmission electronic components, a plurality of reception electronic components 40, a plurality of inductors L0, IC chips 21 and 70, a plurality of external connection terminals 80, and a first resin layer 190, a second resin layer 210, and a metal electrode layer 200.

The plurality of transmission electronic components include, for example, a transmission filter, a matching circuit 3, a first power amplifier PA1, a second power amplifier PA2, a transformer 1, and a capacitor C2 (first capacitor). The matching circuit 3, the first power amplifier PA1, the second power amplifier PA2, the transformer 1, and the capacitor C2 are the same as the matching circuit 3, the first power amplifier PA1, the second power amplifier PA2, the transformer 1, and the capacitor C2 which are described in Embodiment 1.

The plurality of reception electronic components 40 include, for example, reception filters. The IC chip 21 includes, for example, a plurality of low noise amplifiers and a switch circuit. The IC chip 70 includes, for example, a switch circuit. The switch circuit is a switch circuit for switching the connection relationship between a transmission path (a path through which a transmission signal flows) and a reception path (a path through which a reception signal flows), which are included in the radio frequency module 100. The plurality of external connection terminals 80 are electrodes that are electrically connected to pad electrodes of a mother board built in a mobile device such as a smartphone. That is, the external connection terminals 80 are terminals that are electrically connected to the pad electrodes on the surface of the mother board assuming the mounting substrate 9 is mounted on the mother board. The plurality of external connection terminals 80 include the plurality of external connection terminals 4 of Embodiment 1.

As illustrated in FIG. 13, the mounting substrate 9 has a first main surface 91 and a second main surface 92 facing each other in the thickness direction D1 of the mounting substrate 9. On the first main surface 91 of the mounting substrate 9, a plurality of reception electronic components 40, the plurality of inductors L0, the first power amplifier PA1, the second power amplifier PA2, the transformer 1, and the matching circuit 3 are disposed. On the second main surface 92 of the mounting substrate 9, the IC chips 21 and 70, the capacitor C2, and the plurality of external connection terminals 80 (see FIG. 14) are disposed. The capacitor C2 is disposed to overlap the transformer 1 in a thickness direction D2 of the mounting substrate 9.

As illustrated in FIG. 14, the first resin layer 190 is disposed on the first main surface 91 of the mounting substrate 9. The first resin layer 190 includes a member (for example, a resin (for example, an epoxy resin)) having electric insulation. The first resin layer 190 may contain a filler in addition to the resin. The first resin layer 190 exposes a main surface 402 of each of the plurality of electronic components 40 and covers areas other than the main surface 402. In addition, the first resin layer 190 covers the first power amplifier PA1, the second power amplifier PA2, the inductor L0, and the matching circuit 3.

As illustrated in FIG. 14, the second resin layer 210 is disposed on the second main surface 92 of the mounting substrate 9. The second resin layer 210 includes a member (for example, a resin (for example, an epoxy resin)) having electric insulation. The second resin layer 210 may contain a filler in addition to the resin. The second resin layer 210 exposes tip end surfaces of the plurality of external connection terminals 80 and covers areas other than the tip end surfaces. In addition, the second resin layer 210 covers the IC chips 21 and 70 and the capacitor C2.

The metal electrode layer 200 covers the main surfaces 402 of the plurality of electronic components 40, the main surface 191 of the first resin layer 190 on a side opposite to the side of the mounting substrate 9, the outer peripheral surface 193 of the first resin layer 190, the outer peripheral surface 93 of the mounting substrate 9, and the outer peripheral surface 213 of the second resin layer 210. The metal electrode layer 200 is in contact with at least a part of an outer peripheral surface of the ground layer of the mounting substrate 9.

According to Modification Example 5, since the capacitor C2 is disposed on the second main surface 92 (that is, the main surface on the side of the external connection terminal 80) of the mounting substrate 9, a space for disposing the capacitor C2 can be secured without increasing the size of the mounting substrate 9.

In Modification Example 5, a case is illustrated in which the transformer 1 is disposed on the first main surface 91 of the mounting substrate 9. However, the transformer 1 may be included inside the mounting substrate 9. In this case, the multilayer substrate 10 of the transformer 1 is integrally configured with the mounting substrate 9. That is, while the mounting substrate 9 is used as a multilayer substrate and the multilayer substrate is used as the multilayer substrate 10 of the transformer 1, the balanced side coil 6, the first unbalanced side coil portion 71, and the second unbalanced side coil portion 72 of the transformer 1 are included in different layers (dielectric layers) of the mounting substrate 9 (multilayer substrate). In this case, the first main surface 91 and the second main surface 92 of the mounting substrate 9 are the first main surface 10a and the second main surface 10b of the multilayer substrate 10, respectively. In this case, the external connection electrodes 20 are configured by the external connection terminals 80. Therefore, in this case, the capacitor C2 is disposed on the second main surface 92 (main surface on which the external connection terminal 80 is disposed) of the mounting substrate 9 and is disposed the second main surface 10b of the multilayer substrate 10 (the main surface on which the external connection electrodes 20 are disposed).

### Modification Example 6

In Embodiment 1, the wiring pattern portion 8 is disposed on the side of the second main surface 10b of the multilayer substrate 10 in the second unbalanced side coil portion 72, but, in Modification Example 6, the wiring pattern portion 8 is disposed on the side of the first main surface 10a of the multilayer substrate 10 in the multilayer substrate 10 in the first unbalanced side coil portion 71. In this case, the multilayer substrate 10 further has a fifth dielectric layer stacked on the first main surface 11a of the first dielectric layer 11. The fifth dielectric layer has a first main surface and a second main surface on both sides in the thickness direction D1. The first main surface of the fifth dielectric layer becomes the first main surface 10a of the multilayer substrate 10. The wiring pattern portion 8 is disposed on the second main surface of the fifth dielectric layer.

### Modification Example 7

In Embodiment 1, in the transformer 1, the balanced side coil 6 is used as the primary coil (input side coil) and the unbalanced side coil 7 is used as the secondary coil (output side coil), but, in Modification Example 7, the unbalanced side coil 7 is used as the primary coil and the balanced side coil 6 is used as the secondary coil.

### Embodiment 2

### (1) Structure of Transformer

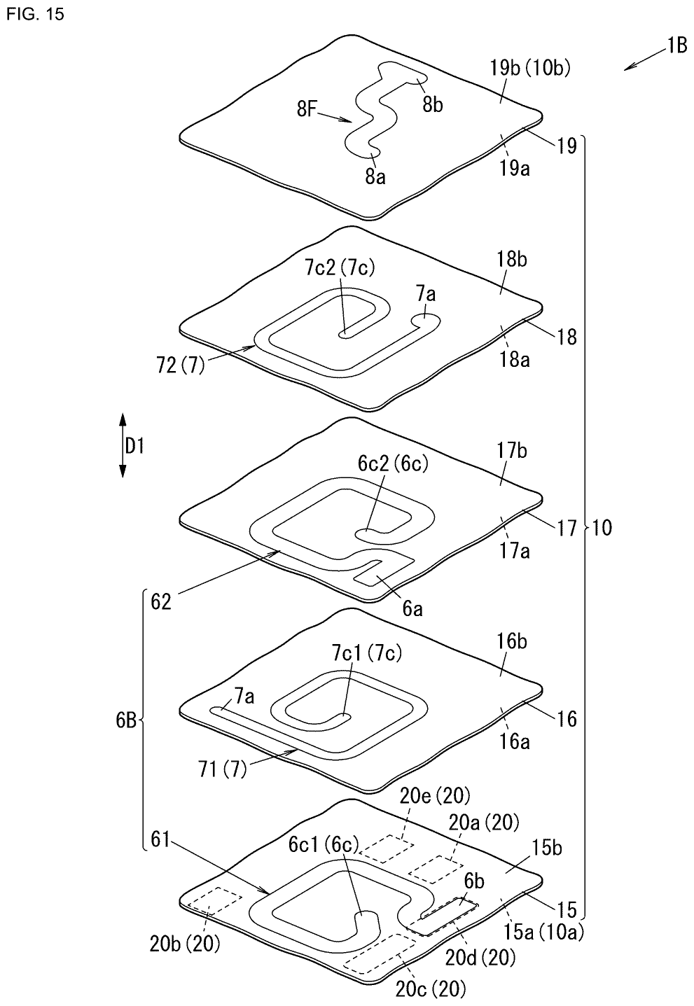

A structure of a transformer 1B of Embodiment 2 will be described with reference to FIGS. 15 to 20. Embodiment 2 may be implemented in combination with Embodiment 1 and modification examples 1 to 5.

Embodiment 2 is different from Embodiment 1 in a fact that a balanced side coil 6B is isolated into a first balanced side coil portion 61 and a second balanced side coil portion 62, and the first balanced side coil portion 61 and the second balanced side coil portion 62 are disposed in dielectric layers different from each other. Further, Embodiment 2 is different from Embodiment 1 in a fact that the wiring pattern portion 8 has a different shape.

As shown in FIG. 15, a multilayer substrate 10 of Embodiment 2 has first to fifth dielectric layers 15 to 19. The first to fifth dielectric layers 15 to 19 have first main surfaces 15a to 19a and second main surfaces 15b to 19b facing each other in a thickness direction D1 of a multilayer substrate 10. The first main surface 10a of the multilayer substrate 10 is the first main surface 15a of the first dielectric layer 15, and the second main surface 10b of the multilayer substrate 10 is the second main surface 19b of the fifth dielectric layer 19.

Further, the balanced side coil 6B of Embodiment 2 has the first balanced side coil portion 61 and the second balanced side coil portion 62.

The first balanced side coil portion 61 is disposed on the second main surface 15b of the first dielectric layer 15. The first unbalanced side coil portion 71 is disposed on the second main surface 16b of the second dielectric layer 16. The second balanced side coil portion 62 is disposed on the second main surface 17b of the third dielectric layer 17. The second unbalanced side coil portion 72 is disposed on the second main surface 18b of the fourth dielectric layer 18. The wiring pattern portion 8F is disposed on the second main surface 19b of the fifth dielectric layer 19. In other words, the first balanced side coil portion 61 is disposed on the side of the first main surface 10a of the multilayer substrate 10 in the first unbalanced side coil portion 71. The second balanced side coil portion 62 is disposed on the side of the second main surface 10b of the multilayer substrate 10 in the first unbalanced side coil portion 71. The second unbalanced side coil portion 72 is disposed on the side of the second main surface 10b of the multilayer substrate 10 in the second balanced side coil portion 62.

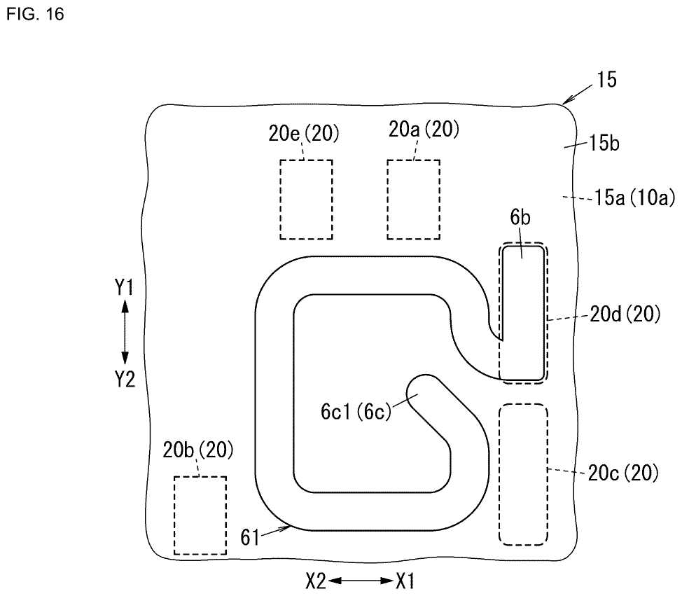

As illustrated in FIG. 16, for example, the first balanced side coil portion 61 is formed to circulate once on the second main surface 15b of the first dielectric layer 15. One end of the first balanced side coil portion 61 is the second end 6b of the balanced side coil 6, and the other end of the first balanced side coil portion 61 is a divided end portion 6cl corresponding to an intermediate tap 6c of the balanced side coil 6. More specifically, the first balanced side coil portion 61 is circulated, for example, a substantially C shape (a quadrangle C shape in the example of FIG. 16). The second end 6b is extended in the first direction X1 and is further extended in the third direction Y1, and is electrically connected to the external connection electrode 20d with a via conductor interposed therebetween. The divided end portion 6cl of the first balanced side coil portion 61 is pulled to the inside of the circumference of the first balanced side coil portion 61, and is electrically connected to a divided end portion 6c2 of the second balanced side coil portion 62, which will be described later, with a via conductor interposed therebetween.

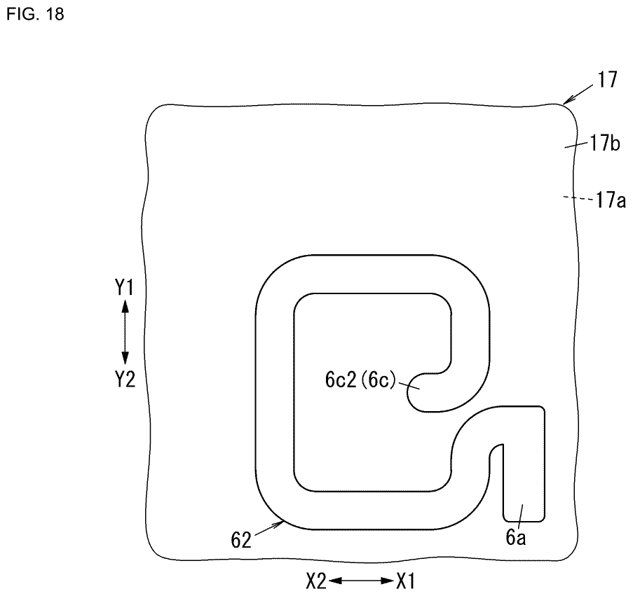

As illustrated in FIG. 18, for example, the second balanced side coil portion 62 is formed to circulate once on the second main surface 17b of the third dielectric layer 17. One end of the second balanced side coil portion 62 is the first end 6a of the balanced side coil 6, and the other end of the second balanced side coil portion 62 is a divided end portion 6c2 corresponding to the intermediate tap 6c of the balanced side coil 6. More specifically, the second balanced side coil portion 62 is circulated, for example, a substantially C shape (a quadrangle C shape in the example of FIG. 18). The second end 6b is extended in the first direction X1 and further extended in the fourth direction Y2, and is electrically connected to the external connection electrode 20c (see FIG. 16) with a via conductor interposed therebetween. The divided end portion 6c2 of the second balanced side coil portion 62 is extended to the inside of the second balanced side coil portion 62, and overlaps the divided end portion 6cl of the first balanced side coil portion 61 in a plan view from the thickness direction D1 (see FIG. 16). The divided end portion 6c2 of the second balanced side coil portion 62 is electrically connected to the divided end portion 6cl (see FIG. 16) of the first balanced side coil portion 61 with a via conductor interposed therebetween.

The C-shaped portion of the second balanced side coil portion 62 other than parts corresponding to both ends 6a and 6c2 overlaps a C-shaped portion of the first balanced side coil portion 61 other than parts corresponding to both ends 6b and 6c1 in a plan view from the thickness direction D1.

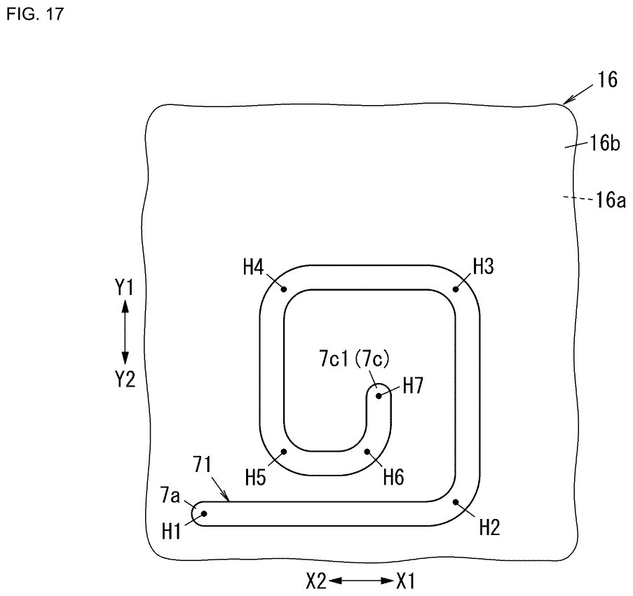

As illustrated in FIG. 17, the first unbalanced side coil portion 71 is formed in a circumferential shape (that is, helical shape) on the second main surface 16b of the second dielectric layer 16. Since the shape of the first unbalanced side coil portion 71 is the same shape as the shape of the first unbalanced side coil portion 71 (see FIG. 3) of Embodiment 1, detailed description is omitted.

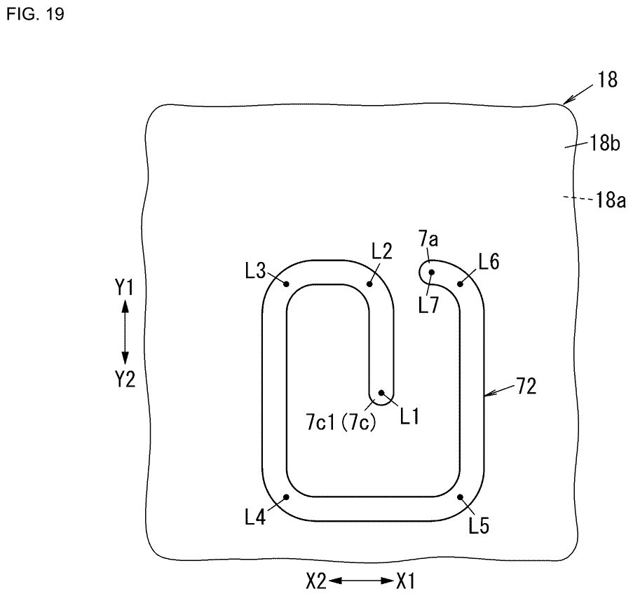

As illustrated in FIG. 19, the second unbalanced side coil portion 72 is formed in a circumferential shape (that is, helical shape) on the second main surface 18b of the fourth dielectric layer 18. Since the shape of the second unbalanced side coil portion 72 is the same shape as the shape of the second unbalanced side coil portion 72 (see FIG. 5) of Embodiment 1, detailed description is omitted.

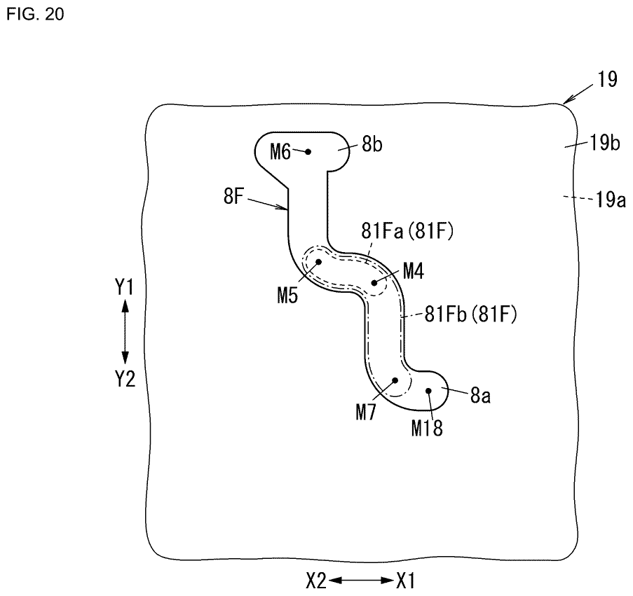

As illustrated in FIG. 20, the wiring pattern portion 8F is formed on the second main surface 19b of the fifth dielectric layer 19 to circulate to overlap at least a part of the unbalanced side coil 7 in the peripheral direction from the end portion M18 that overlaps the divided end portion 6c2 of the second balanced side coil portion 62 to the end portion M6 in a plan view from the thickness direction D1. More specifically, the wiring pattern portion 8F is formed on the second main surface 19b of the fifth dielectric layer 19 to reach the end portion M6 from the end portion M18 through each of the positions M7, M4, and M5. The end portion M18 is a position that overlaps the divided end portion 6c2 (see FIG. 18) of the second balanced side coil portion 62 in a plan view from the thickness direction D1. The positions M7, M4, and M5 are the same positions as the positions M7, M4, and M5 of Modification Example 3.

As shown in FIG. 20, the wiring pattern portion 8F has an overlapping portion 81F that overlaps the unbalanced side coil 7 along the peripheral direction in a plan view from the thickness direction D1. The overlapping portion 81F includes a part along the positions M7, M4, and M5 of the wiring pattern portion 8F. The overlapping portion 81F has a first overlapping portion 81Fa and a second overlapping portion 81Fb. The first overlapping portion 81Fa is a part that overlaps the first unbalanced side coil portion 71 in a plan view from the thickness direction D1, and includes a part along the positions M4 and M5 of the wiring pattern portion 8F. The second overlapping portion 81Fb is a part that overlaps the second unbalanced side coil portion 72 in a plan view from the thickness direction D1, and includes a part along the positions M7, M4, and M5 of the wiring pattern portion 8F.

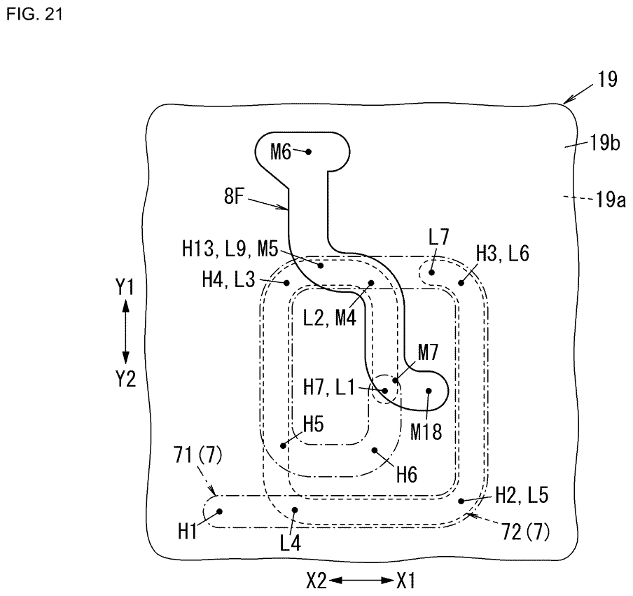

As illustrated in FIG. 21, the first overlapping portion 81Fa (a part along the positions M4 and M5) overlaps a part along the positions H8 and H13 of the first unbalanced side coil portion 71. The positions H8 and H13 are the same positions as the positions H8 and H13 of Embodiment 1. The second overlapping portion 81Fb (a part along the positions M7, M4, and M5) overlaps a part along the end portion L1, the position L2, and the position L9 of the second unbalanced side coil portion 72. The end portion L1, the position L2, and the position L9 are the same positions as the end portion L1, the position L2, and the position L9 of Embodiment 1.

In Embodiment 2, similarly to the wiring pattern portion 8 of Embodiment 1, the wiring pattern portion 8F has the overlapping portion 81F, so that the electromagnetic coupling between the wiring pattern portion 8F and the unbalanced side coil 7 can be strengthened.

### (2) Modification Examples

Hereinafter, modification examples of the transformer 1 of Embodiment 2 will be described. The following modification examples may be implemented in combination with Embodiment 1, the modification examples thereof, and Embodiment 2. In the following description, the same configurations as in the embodiment are attached with the same reference numerals and the description thereof is omitted, and only configurations different from the embodiment may be described.

### Modification Example 1

In Embodiment 2, the second unbalanced side coil portion 72 is disposed on the side of the second main surface 10b of the second balanced side coil portion 62, but, in Modification Example 1, the second unbalanced side coil portion 72 is disposed on the side of the first main surface 10a of the multilayer substrate 10 in the first balanced side coil portion 61. In this case, the multilayer substrate 10 further has a sixth dielectric layer stacked on the first main surface 15a of the first dielectric layer 15. The sixth dielectric layer has a first main surface and a second main surface on both sides in the thickness direction D1. The first main surface of the sixth dielectric layer becomes the first main surface 10a of the multilayer substrate 10. For example, the second unbalanced side coil portion 72 is disposed on the second main surface of the sixth dielectric layer. In this case, further, the wiring pattern portion 8F may be disposed on the side of the first main surface 10a of the multilayer substrate 10 in the second unbalanced side coil portion 72. In this case, the multilayer substrate 10 further has a seventh dielectric layer stacked on the first main surface of the sixth dielectric layer. The seventh dielectric layer has a first main surface and a second main surface on both sides in the thickness direction D1. The first main surface of the seventh dielectric layer becomes the first main surface 10a of the multilayer substrate 10. The wiring pattern portion 8F is disposed on the second main surface of the seventh dielectric layer.

### Aspects

The following aspects are disclosed from the embodiments and the modification examples described above.

According to a first aspect, a transformer (1; 1B) includes a balanced side coil (6; 6B), an unbalanced side coil (7), an external connection wiring pattern portion (8; 8B; 8C; 8D; 8E; 8F), and a multilayer substrate (10). The balanced side coil (6; 6B) has a first end (6a), a second end (6b), and an intermediate tap (6c) included between the first end (6a) and the second end (6b). The unbalanced side coil (7) has a third end (7a) and a fourth end (7b). The fourth end (7b) is grounded. The wiring pattern portion (8; 8B; 8C; 8D; 8E; 8F) is electrically connected to the intermediate tap (6c). A multilayer substrate (10) has a plurality of dielectric layers (11 to 14; 15 to 19). The balanced side coil (6; 6B), the unbalanced side coil (7), and the wiring pattern portion (8; 8B; 8C; 8D; 8E; 8F) are disposed on dielectric layers different from each other in the plurality of dielectric layers (11 to 14; 15 to 19) of the multilayer substrate (10). The balanced side coil (6; 6B) and the unbalanced side coil (7) at least partially overlap each other in a plan view from a thickness direction (D1) of the multilayer substrate (10). A wiring pattern portion (8; 8B; 8C; 8D; 8E; 8F) has an overlapping portion (81; 81B; 81C; 81D; 81E; 8F) that overlaps the unbalanced side coil (7) along a peripheral direction in a plan view from the thickness direction (D1) of the multilayer substrate (10).

According to this configuration, the wiring pattern portion (8; 8B; 8C; 8D; 8E; 8F) has an overlapping portion (81; 81B; 81C; 81D; 81E; 8F) that overlaps the unbalanced side coil (7) along a peripheral direction in a plan view from the thickness direction (D1) of the multilayer substrate (10). Accordingly, the wiring pattern portion (8; 8B; 8C; 8D; 8E; 8F) (especially the overlapping portion (81; 81B; 81C; 81D; 81E; 8F)) is used as a part of the balanced side coil (6; 6B), so that the electromagnetic coupling between the wiring pattern portion (8; 8B; 8C; 8D; 8E; 8F) and the unbalanced side coil (7) can be strengthened. As a result, a coupling coefficient of the transformer (1; 1B) can be increased. In this configuration, in order to increase the coupling coefficient of the transformer (1; 1B), the number of turns need not be increased or the line width need not be narrowed in the balanced side coil (6; 6B) and the unbalanced side coil (7). Therefore, the increase in size of the transformer (1; 1B) and a signal loss in the transformer (1; 1B) can be suppressed. As above, the coupling coefficient of the transformer can be increased by suppressing the increase in size of the transformer (1; 1B) and the signal loss in the transformer (1; 1B).

In addition, since the overlapping portion (81; 81B; 81C; 81D; 81E; 8F) overlaps the unbalanced side coil (7) along the peripheral direction in a plan view from the thickness direction (D1) of the multilayer substrate (10), the wiring pattern portion (8; 8B; 8C; 8D; 8E; 8F) is formed so as not to intersect a central part (a part where the magnetic fields generated by the balanced side coil (6; 6B) and the unbalanced side coil (7) are concentrated) of each of the cavities of the balanced side coil (6; 6B) and the unbalanced side coil (7). Therefore, it is possible to suppress the disturbance of the magnetic fields generated by the balanced side coil (6; 6B) and the unbalanced side coil (7). As a result, deterioration in the coupling state between the balanced side coil (6; 6B) and the unbalanced side coil (7) can be suppressed, and the coupling coefficient of the transformer (1; 1B) can be increased.

According to a second aspect, in the transformer (1; 1B) of the first aspect, the multilayer substrate (10) has a first main surface (10a) and a second main surface (10b). The unbalanced side coil (7) has a first unbalanced side coil portion (71) and a second unbalanced side coil portion (72). The first unbalanced side coil portion (71) and the second unbalanced side coil portion (72) are disposed in dielectric layers different from each other in the plurality of dielectric layers (11 to 14; 15 to 19) of the multilayer substrate (10). The first unbalanced side coil portion (71) is disposed on a side of the first main surface (10a) of the multilayer substrate (10) in the balanced side coil (6; 6B). The second unbalanced side coil portion (72) is disposed on a side of the second main surface (10b) of the multilayer substrate (10) in the balanced side coil (6; 6B).

According to this configuration, since the balanced side coil (6; 6B) is disposed between the first unbalanced side coil portion (71) and the second unbalanced side coil portion (72), the magnetic field coupling between the balanced side coil (6; 6B) and the unbalanced side coil (7) can be strengthened.

According to a third aspect, in the transformer (1, 1B) of the second aspect, the wiring pattern portion (8; 8B; 8C; 8D; 8E; 8F) is disposed on the side of the first main surface (10a) of the multilayer substrate (10) in the first unbalanced side coil portion (71) or is disposed on the side of the second main surface (10b) of the multilayer substrate (10) in the second unbalanced side coil portion (72).

According to this configuration, since the balanced side coil (6; 6B) using the wiring pattern portion (8; 8B; 8C; 8D; 8E; 8F) and the unbalanced side coil (7) are disposed alternately in the thickness direction (D1) of the multilayer substrate (10), a magnetic field coupling between the balanced side coil (6; 6B) and the unbalanced side coil (7) can be strengthened.

According to a fourth aspect, in the transformer (1) of the second or third aspect, the overlapping portion (81; 81B; 81D; 81E; 81F) has a first overlapping portion (81a; 81Ba; 81Da; 81Ea; 8Fa) and a second overlapping portion (81b; 81Bb; 81 Db; 81Eb; 81Fb). The first overlapping portion (81a; 81Ba; 81Da; 81Ea; 81Fa) overlaps the first unbalanced side coil portion (71) along the peripheral direction in a plan view from the thickness direction (D1) of the multilayer substrate (10). The second overlapping portion (81b; 81Bb; 81Db; 81Eb; 81Fb) overlaps the second unbalanced side coil portion (72) along a peripheral direction in a plan view from the thickness direction (D1) of the multilayer substrate (10). In a plan view from the thickness direction (D1) of the multilayer substrate (10), the first overlapping portion (81a; 81Ba; 81Da; 81Ea; 81Fa) and the second overlapping portion (81b; 81Bb; 81Db; 81Eb; 81Fb) are regions different from each other.

According to this configuration, in a plan view from the thickness direction (D1) of the multilayer substrate (10), the first overlapping portion (81a; 81Ba; 81Da; 81Ea; 81Fa) and the second overlapping portion (81b; 81Bb; 81Db; 81Eb; 81Fb) are regions different from each other. For this reason, it is possible to suppress mutual interference in a magnetic field coupling between the first overlapping portion (81a; 81Ba; 81Da; 81Ea; 81Fa) and the first unbalanced side coil portion (71) and a magnetic field coupling between the second overlapping portion (81b; 81Bb; 81Db; 81Eb; 81Fb) and the second unbalanced side coil portion (72). As a result, the wiring pattern portion (8; 8B; 8D; 8E; 8F) can realize stronger magnetic field coupling with both the first unbalanced side coil portion (71) and the second unbalanced side coil portion (72).

According to a fifth aspect, in the transformer (1, 1B) of any one of the first to fourth aspects, a first line width (W3) of the balanced side coil (6; 6B) and a second line width (W1, W2) of the unbalanced side coil (7) are widths different from each other in a plan view from the thickness direction (D1) of the multilayer substrate (10).

According to this configuration, even assuming the balanced side coil (6; 6B) and the unbalanced side coil (7) are deviated from each other in a main surface direction of the multilayer substrate (10), it is possible to suppress the change in the coupling coefficient with respect to the deviation.

According to a sixth aspect, in the transformer (1, 1B) of the fifth aspect, the first line width (W3) of the balanced side coil (6) is larger than the second line width (W1, W2) of the unbalanced side coil (7).

According to this configuration, the electric resistance of the balanced side coil (6, 6B) can be made smaller than the electric resistance of the unbalanced side coil (7). As a result, assuming the output sections of the first power amplifier (PA1) and the second power amplifier (PA2) are respectively connected to the first end (6a) and the second end (6b) of the balanced side coil (6, 6B), loss due to the electric resistance of each of the outputs of the first power amplifier (PA1) and the second power amplifier (PA2) can be reduced.

According to a seventh aspect, in the transformer (1, 1B) of any one of the first to sixth aspects further includes a capacitor (C2) connected between the intermediate tap (6c) and a ground.

According to this configuration, assuming DC power is supplied from the outside to the intermediate tap (6c), a radio frequency noise component included in DC power can be removed by the capacitor (C2).

According to an eighth aspect, in the transformer (1, 1B) of the seventh aspect, the multilayer substrate (10) has a first main surface (10a) and a second main surface (10b). The transformer (1, 1B) further includes an external connection electrode (20) disposed on one main surface of the first main surface (10a) and the second main surface (10b). The capacitor (C2) is disposed on one main surface (10a) of the multilayer substrate (10).

According to this configuration, since the capacitor (C2) is disposed on the back surface of the multilayer substrate (10) (that is, the main surface on the side of the external connection electrode (20)), a space for disposing the capacitor (C2) can be secured without increasing the size of the multilayer substrate (10).

According to a ninth aspect, in the transformer (1B) of the first aspect, the multilayer substrate (10) has a first main surface (10a) and a second main surface (10b). The unbalanced side coil (7) has a first unbalanced side coil portion (71) and a second unbalanced side coil portion (72). The balanced side coil (6B) has a first balanced side coil portion (61) and a second balanced side coil portion (62). The first unbalanced side coil portion (71), the second unbalanced side coil portion (72), the first balanced side coil portion (61), and the second balanced side coil portion (62) are disposed on dielectric layers different from each other in the plurality of dielectric layers (15 to 19) of the multilayer substrate (10). The first balanced side coil portion (61) is disposed on a side of the first main surface (10a) of the multilayer substrate (10) in the first unbalanced side coil portion (71). The second balanced side coil portion (62) is disposed on a side of the second main surface (10b) of the multilayer substrate (10) in the first unbalanced side coil portion (71). The second unbalanced side coil portion (72) is disposed on the side of the first main surface (10a) of the multilayer substrate (10) in the first balanced side coil portion (61) or on the side of the second main surface (10b) of the multilayer substrate (10) in the second balanced side coil portion (62).

According to this configuration, since the first balanced side coil portion (61) and the second balanced side coil portion (62) of the balanced side coil (6B) and the first unbalanced side coil portion (71) and the second unbalanced side coil portion (72) of the unbalanced side coil (7) are disposed alternately in the thickness direction (D1) of the multilayer substrate (10), a magnetic field coupling between the balanced side coil (6B) and the unbalanced side coil (7) can be strengthened.

According to a tenth aspect, in the radio frequency module (100) of the ninth aspect, the wiring pattern portion (8F) is disposed on the side of the first main surface (10a) of the multilayer substrate (10) in the second unbalanced side coil portion (72) assuming the second unbalanced side coil portion (72) is disposed on the side of the first main surface (10a) of the multilayer substrate (10) in the first balanced side coil portion (61). The wiring pattern portion (8F) is disposed on the side of the second main surface (10b) of the multilayer substrate (10) in the first unbalanced side coil portion (71) assuming the second unbalanced side coil portion (72) is disposed on the side of the second main surface (10b) of the multilayer substrate (10) in the second balanced side coil portion (62).

According to this configuration, since the balanced side coil (6B) using the wiring pattern portion (8F) and the unbalanced side coil (7) are disposed alternately in the thickness direction (D1) of the multilayer substrate (10), a magnetic field coupling between the balanced side coil (6B) and the unbalanced side coil (7) can be strengthened.

According to an eleventh aspect, a radio frequency module (100) includes the transformer (1, 1B) according to any one of first to tenth aspects, a first input terminal (4a) and a second input terminal (4b), and a first power amplifier (PA1) and a second power amplifier (PA2). The first power amplifier (PA1) amplifies a first balanced signal (S1) input from the first input terminal (4a), and outputs a resulting signal to the first end (6a) of the transformer (1). The second power amplifier (PA2) amplifies a second balanced signal (S2) input from the second input terminal (4b), and outputs a resulting signal to the second end (6b) of the transformer (1).

According to this configuration, it is possible to provide the radio frequency module (100) including the transformer (1, 1B).

According to a twelfth aspect, the radio frequency module (100) of the eleventh aspect further includes a capacitor (C1) that is provided to electrically connect an output section of the first power amplifier (PA1) and an output section of the second power amplifier (PA2).

According to this configuration, the capacitor (C1) can remove radio frequency noise components included in the balanced signal (first balanced signal (S1) and the second balanced signal (S2)) input to the first end (6a) and the second end (6b) of the balanced side coil (6, 6B).

According to a thirteenth aspect, the radio frequency module (100) of the eleventh or twelfth aspect includes a mounting substrate (9) and an external connection terminal (80). The mounting substrate (9) has a first main surface (91) and a second main surface (92). The external connection terminal (80) is provided on the second main surface (92) of the mounting substrate (9). The transformer (1) further includes a capacitor (C2). The capacitor (C2) is connected between the intermediate tap (6c) and a ground and disposed on the second main surface (92) of the mounting substrate (9).

According to this configuration, since the capacitor (C2) is disposed on the back surface of the mounting substrate (9) (that is, the main surface on the side of the external connection terminal (80)), a space for disposing the capacitor (C2) can be secured without increasing the size of the mounting substrate (9).

### REFERENCE SIGNS LIST

1, 1B TRANSFORMER
3 MATCHING CIRCUIT
4 EXTERNAL CONNECTION TERMINAL
4a FIRST INPUT TERMINAL
4b SECOND INPUT TERMINAL
4c OUTPUT TERMINAL
4d POWER SUPPLY TERMINAL
6, 6B BALANCED SIDE COIL
6a FIRST END
6b SECOND END
6c INTERMEDIATE TAP
6c1, 6c2 DIVIDED END PORTION
7 UNBALANCED SIDE COIL
7a THIRD END
7b FOURTH END
7c POSITION
7c1, 7c2 DIVIDED END PORTION
8 WIRING PATTERN PORTION
8a, 8b ONE END
8B to 8F WIRING PATTERN PORTION
9 MOUNTING SUBSTRATE
91 FIRST MAIN SURFACE
92 SECOND MAIN SURFACE
10: MULTILAYER SUBSTRATE
10a FIRST MAIN SURFACE
10b SECOND MAIN SURFACE
11 to 14, 15 to 19 DIELECTRIC LAYER
11, 15 FIRST DIELECTRIC LAYER
12, 16 SECOND DIELECTRIC LAYER
13, 17 THIRD DIELECTRIC LAYER
14, 18 FOURTH DIELECTRIC LAYER
19 FIFTH DIELECTRIC LAYER
11a to 14a, 15a to 19a FIRST MAIN SURFACE
11b to 14b, 15b to 19b SECOND MAIN SURFACE
20, 20a to 20e EXTERNAL CONNECTION ELECTRODE
40 RECEPTION ELECTRONIC COMPONENT
61 FIRST BALANCED SIDE COIL PORTION
62 SECOND BALANCED SIDE COIL PORTION
71 FIRST UNBALANCED SIDE COIL PORTION
72 SECOND UNBALANCED SIDE COIL PORTION
80 EXTERNAL CONNECTION TERMINAL
81, 81B to 8F OVERLAPPING PORTION
81a, 81Ba, 81Da, 81Ea, 81Fa FIRST OVERLAPPING PORTION
81b, 81Bb, 81Db, 81Eb, 81Fb SECOND OVERLAPPING PORTION
100 RADIO FREQUENCY MODULE
200 METAL ELECTRODE LAYER
190 FIRST RESIN LAYER
210 SECOND RESIN LAYER
300 WIRING PATTERN PORTION
C1 to C3 CAPACITOR
D1 THICKNESS DIRECTION
H1 to H13 POSITION
L1 to L9, L11, L12 POSITION
L21, L22 INDUCTOR
M1 to M16, M17 to M10 POSITION
PA1 FIRST POWER AMPLIFIER
PA2 SECOND POWER AMPLIFIER
S1 FIRST BALANCED SIGNAL
S2 SECOND BALANCED SIGNAL
S3 UNBALANCED SIGNAL
W1 LINE WIDTH (SECOND LINE WIDTH)
W2 LINE WIDTH (SECOND LINE WIDTH)
W3 LINE WIDTH (FIRST LINE WIDTH)
W4 LINE WIDTH
X1 FIRST DIRECTION
X2 SECOND DIRECTION
Y1 THIRD DIRECTION
Y2 FOURTH DIRECTION

1. A transformer comprising:
a balanced side coil that has a first end, a second end, and an intermediate tap included between the first end and the second end;
an unbalanced side coil that has a third end and a fourth end, the fourth end being grounded;
an external connection wiring pattern portion that is electrically connected to the intermediate tap; and
a multilayer substrate that has a plurality of dielectric layers, wherein
the balanced side coil, the unbalanced side coil, and the wiring pattern portion are disposed on dielectric layers different from each other in the plurality of dielectric layers of the multilayer substrate,
the balanced side coil and the unbalanced side coil at least partially overlap each other in a plan view from a thickness direction of the multilayer substrate, and
the wiring pattern portion has an overlapping portion that overlaps the unbalanced side coil along a peripheral direction in a plan view from the thickness direction of the multilayer substrate.

2. The transformer according to claim 1, wherein
the multilayer substrate has a first main surface and a second main surface,
the unbalanced side coil has
a first unbalanced side coil portion, and
a second unbalanced side coil portion,
the first unbalanced side coil portion and the second unbalanced side coil portion are disposed in dielectric layers different from each other in the plurality of dielectric layers of the multilayer substrate,
the first unbalanced side coil portion is disposed on a side of the first main surface of the multilayer substrate in the balanced side coil, and
the second unbalanced side coil portion is disposed on a side of the second main surface of the multilayer substrate in the balanced side coil.

3. The transformer according to claim 2, wherein
the wiring pattern portion is disposed on the side of the first main surface of the multilayer substrate in the first unbalanced side coil portion or is disposed on the side of the second main surface of the multilayer substrate in the second unbalanced side coil portion.

4. The transformer according to claim 3, wherein
the overlapping portion has
a first overlapping portion that overlaps the first unbalanced side coil portion along the peripheral direction in a plan view from the thickness direction of the multilayer substrate, and
a second overlapping portion that overlaps the second unbalanced side coil portion along the peripheral direction in a plan view from the thickness direction of the multilayer substrate, and
the first overlapping portion and the second overlapping portion are regions different from each other in a plan view from the thickness direction of the multilayer substrate.

5. The transformer according to claim 4, wherein
a first line width of the balanced side coil and a second line width of the unbalanced side coil are widths different from each other in a plan view from the thickness direction of the multilayer substrate.

6. The transformer according to claim 5, wherein
the first line width of the balanced side coil is larger than the second line width of the unbalanced side coil.

7. The transformer according to claim 6, further comprising:
a capacitor connected between the intermediate tap and a ground.

8. The transformer according to claim 7, wherein
the multilayer substrate has a first main surface and a second main surface,
the transformer further comprises an external connection electrode disposed on one main surface of the first main surface and the second main surface, and
the capacitor is disposed on the one main surface of the multilayer substrate.

9. The transformer according to claim 1, wherein
the multilayer substrate has a first main surface and a second main surface,
the unbalanced side coil has
a first unbalanced side coil portion, and
a second unbalanced side coil portion,
the balanced side coil has
a first balanced side coil portion, and
a second balanced side coil portion,
the first unbalanced side coil portion, the second unbalanced side coil portion, the first balanced side coil portion, and the second balanced side coil portion are disposed on dielectric layers different from each other in the plurality of dielectric layers of the multilayer substrate,
the first balanced side coil portion is disposed on a side of the first main surface of the multilayer substrate in the first unbalanced side coil portion,
the second balanced side coil portion is disposed on a side of the second main surface of the multilayer substrate in the first unbalanced side coil portion, and
the second unbalanced side coil portion is disposed on the side of the first main surface of the multilayer substrate in the first balanced side coil portion or on the side of the second main surface of the multilayer substrate in the second balanced side coil portion.

10. The transformer according to claim 9, wherein
the wiring pattern portion
is disposed on the side of the first main surface of the multilayer substrate in the second unbalanced side coil portion assuming the second unbalanced side coil portion is disposed on the side of the first main surface of the multilayer substrate in the first balanced side coil portion, and
is disposed on the side of the second main surface of the multilayer substrate in the first unbalanced side coil portion assuming the second unbalanced side coil portion is disposed on the side of the second main surface of the multilayer substrate in the second balanced side coil portion.

11. A radio frequency module comprising:
the transformer according to claim 10;
a first input terminal and a second input terminal;
a first power amplifier that amplifies a first balanced signal input from the first input terminal and outputs a resulting signal to the first end of the transformer; and
a second power amplifier that amplifies a second balanced signal input from the second input terminal and outputs a resulting signal to the second end of the transformer.

12. The radio frequency module according to claim 11, further comprising:
a capacitor that is provided to electrically connect an output section of the first power amplifier and an output section of the second power amplifier.

13. The radio frequency module according to claim 12, further comprising:
a mounting substrate that has a first main surface and a second main surface; and
an external connection terminal that is provided on the second main surface of the mounting substrate, wherein
the transformer further includes a capacitor that is connected between the intermediate tap and a ground and disposed on the second main surface of the mounting substrate.

14. The transformer according to claim 2, wherein
the overlapping portion has
a first overlapping portion that overlaps the first unbalanced side coil portion along the peripheral direction in a plan view from the thickness direction of the multilayer substrate, and
a second overlapping portion that overlaps the second unbalanced side coil portion along the peripheral direction in a plan view from the thickness direction of the multilayer substrate, and
the first overlapping portion and the second overlapping portion are regions different from each other in a plan view from the thickness direction of the multilayer substrate.

15. The transformer according to claim 14, wherein
a first line width of the balanced side coil and a second line width of the unbalanced side coil are widths different from each other in a plan view from the thickness direction of the multilayer substrate.

16. The transformer according to claim 15, wherein
the first line width of the balanced side coil is larger than the second line width of the unbalanced side coil.

17. The transformer according to claim 16, further comprising:
a capacitor connected between the intermediate tap and a ground.

18. The transformer according to claim 17, wherein
the multilayer substrate has a first main surface and a second main surface,
the transformer further comprises an external connection electrode disposed on one main surface of the first main surface and the second main surface, and
the capacitor is disposed on the one main surface of the multilayer substrate.

19. A radio frequency module comprising:
the transformer according to claim 1;
a first input terminal and a second input terminal;
a first power amplifier that amplifies a first balanced signal input from the first input terminal and outputs a resulting signal to the first end of the transformer; and
a second power amplifier that amplifies a second balanced signal input from the second input terminal and outputs a resulting signal to the second end of the transformer.

20. The radio frequency module according to claim 19, further comprising:
a capacitor that is provided to electrically connect an output section of the first power amplifier and an output section of the second power amplifier.
